(19) United States
(12) Patent Application Publication
(10) Pub. No.: US 2024/0419072 A1
(43) Pub. Date: Dec. 19, 2024

(54) ACTIVE LIGHT RAY SENSITIVE OR RADIOACTIVE RAY SENSITIVE RESIN COMPOSITION, RESIST FILM, PATTERN-FORMING METHOD, AND METHOD FOR MANUFACTURING ELECTRONIC DEVICE

(71) Applicant: FUJIFILM Corporation, Tokyo (JP)

(72) Inventors: Takeshi KAWABATA, Haibara-gun (JP); Akiyoshi GOTO, Haibara-gun (JP)

(73) Assignee: FUJIFILM Corporation, Tokyo (JP)

(21) Appl. No.: 18/808,427

(22) Filed: Aug. 19, 2024

Related U.S. Application Data
(63) Continuation of application No. PCT/JP2023/008868, filed on Mar. 8, 2023.

(30) Foreign Application Priority Data
Mar. 23, 2022 (JP) 2022-047069

(51) Int. Cl. G03F 7/039; G03F 7/004; G03F 7/20

(52) U.S. Cl. CPC G03F 7/039; G03F 7/0042; G03F 7/0048; G03F 7/2004; G03F 7/2037; G03F 7/2039

(57) ABSTRACT

A first object of the present invention is to provide an active light ray sensitive or radioactive ray sensitive resin composition having excellent sensitivity and forming a pattern with excellent resolution. A second object of the present invention is to provide a resist film, a pattern-forming method, and a method for manufacturing an electronic device relating to the active light ray sensitive or radioactive ray sensitive resin composition. The active light ray sensitive or radioactive ray sensitive resin composition of the present invention includes a metal compound, a resin having a main chain that is decomposed by irradiation with an X-ray, an electron beam, or an extreme ultraviolet ray, and a solvent, wherein the metal compound includes one or more metal compounds selected from the group consisting of a metal complex, an organic metal salt, and an organic metal compound, and the resin includes a resin including a repeating unit represented by a formula (1) or a repeating unit represented by a formula (XR0).

### CROSS-REFERENCE TO RELATED APPLICATIONS

This application is a Continuation of PCT International Application No. PCT/JP2023/008868 filed on Mar. 8, 2023, which claims priority under 35 U.S.C. § 119 (a) to Japanese Patent Application No. 2022-047069 filed on Mar. 23, 2022. The above applications are hereby expressly incorporated by reference, in their entirety, into the present application.

### BACKGROUND OF THE INVENTION

### 1. Field of the Invention

The present invention relates to an active light ray sensitive or radioactive ray sensitive resin composition, a resist film, a pattern-forming method, and a method for manufacturing an electronic device.

### 2. Description of the Related Art

A pattern-forming method utilizing chemical amplification has been used for complementing the sensitivity reduction due to light absorption after resisting for a KrF excimer laser (248 nm). For example, in a positive chemical amplification method, the photoacid generator included in an exposed portion is first decomposed by light irradiation to generate an acid. Then, in a process of post exposure baking (PEB) or the like, the catalytic action of the generated acid changes the solubility in developer by, for example, changing an alkali-insoluble group possessed by the resin included in an active light ray sensitive or radioactive ray sensitive resin composition to an alkali-soluble group. Subsequently, for example, development is performed using a basic aqueous solution. Consequently, the exposed portion is removed to obtain a desired pattern.

To miniaturize semiconductor elements, a decrease in wavelength of an exposure light source and an increase in the number of apertures of a projection lens (high NA) have progressed, and currently, an exposure machine using an ArF excimer laser having a wavelength of 193 nm as the light source has been developed. In addition, a pattern-forming method using an extreme ultraviolet ray (extreme ultraviolet (EUV) light) or an electron beam (EB) as a light source is also being considered in those days.

Under such a situation, various configurations have been proposed as the active light ray sensitive or radioactive ray sensitive resin composition.

For example, JP 2019-211531A discloses a positive resist composition for EUV lithography, the composition including a polymer that increases the solubility in developer by cutting the main chain through irradiation with an extreme ultraviolet ray (EUV).

### SUMMARY OF THE INVENTION

The present inventors prepared and examined active light ray sensitive or radioactive ray sensitive resin compositions with reference to JP 2019-211531A and revealed that there is a room for further improving the sensitivity. In addition, similarly, it has also been revealed that there is a room for further improving the resolution.

Accordingly, it is an object of the present invention to provide an active light ray sensitive or radioactive ray sensitive resin composition having excellent sensitivity and forming a pattern with excellent resolution.

In addition, it is an object of the present invention to provide a resist film, a pattern-forming method, and a method for manufacturing an electronic device relating to the active light ray sensitive or radioactive ray sensitive resin composition.

The present inventors found that the above issues can be solved by the following configurations:

[1] An active light ray sensitive or radioactive ray sensitive resin composition including:
a metal compound;
a resin having a main chain that is decomposed by irradiation with an X-ray, an electron beam, or an extreme ultraviolet ray; and
a solvent, wherein the metal compound is one or more selected from the group consisting of a metal complex, an organic metal salt, and an organic metal compound, and the resin includes a repeating unit represented by a formula (1) described later or a repeating unit represented by a formula (XR) described later.

[2] The active light ray sensitive or radioactive ray sensitive resin composition according to [1], wherein the resin includes one or more functional groups selected from the group consisting of a hydroxy group, a carboxyl group, an amino group, an amide group, a thiol group, and an acetoxy group.

[3] The active light ray sensitive or radioactive ray sensitive resin composition according to [1] or [2], wherein the resin includes one or more functional groups selected from the group consisting of a phenolic hydroxy group and a carboxyl group.

[4] The active light ray sensitive or radioactive ray sensitive resin composition according to any one of [1] to [3], wherein the repeating unit represented by the formula (1) includes a repeating unit represented by a formula (1A) described later.

[5] The active light ray sensitive or radioactive ray sensitive resin composition according to any one of [1] to [4], wherein X represents a chlorine atom.

[6] The active light ray sensitive or radioactive ray sensitive resin composition according to any one of [1] to [5], wherein the resin includes a repeating unit represented by the formula (1) and a repeating unit represented by a formula (3) described later.

[7] The active light ray sensitive or radioactive ray sensitive resin composition according to [6], wherein C¹ includes one or more functional groups selected from the group consisting of a phenolic hydroxy group and a carboxyl group.

[8] The active light ray sensitive or radioactive ray sensitive resin composition according to any one of [1] to [7], wherein the metal compound includes one or more metal atoms selected from the group consisting of an iron atom, a titanium atom, a cobalt atom, a nickel atom, a zinc atom, a silver atom, an indium atom, a tin atom, and a hafnium atom.

[9] The active light ray sensitive or radioactive ray sensitive resin composition according to any one of [1] to [8], wherein a content of the metal compound is 1 to 40 mass % relative to a content of the resin.

[10] The active light ray sensitive or radioactive ray sensitive resin composition according to any one of [1] to [9], further including a photodegradable onium salt compound.

[11] A resist film formed using the active light ray sensitive or radioactive ray sensitive resin composition according to any one of [1] to [10].

[12] A pattern-forming method having:
a step of forming a resist film on a substrate using the active light ray sensitive or radioactive ray sensitive resin composition according to any one of [1] to [10];
a step of exposing the resist film to an X-ray, an electron beam, or an extreme ultraviolet ray; and
a step of developing the exposed resist film using a developer.

[13] A method for manufacturing an electronic device, the method including the pattern-forming method according to [12].

According to the present invention, it is possible to provide an active light ray sensitive or radioactive ray sensitive resin composition that has excellent sensitivity and forms a pattern with excellent resolution.

In addition, the present invention can provide a resist film, a pattern-forming method, and a method for manufacturing an electronic device relating to the active light ray sensitive or radioactive ray sensitive resin composition.

### DESCRIPTION OF THE PREFERRED EMBODIMENTS

The present invention will now be described in detail.

The explanation of the configuration requirements described below may be based on a typical embodiment of the present invention, but the present invention is not limited to the embodiment.

The term “organic group” in the present specification refers to a group including at least one carbon atom.

The term “active light ray” or “radioactive ray” in the present specification means, for example, a far ultraviolet ray, an extreme ultraviolet ray (EUV), an X-ray, and an electron beam (EB), represented by a bright-line spectrum of a mercury lamp and an excimer laser. The term “light” in the present specification means an active light ray or a radioactive ray.

The term “exposure” in the present specification includes not only exposure to a far ultraviolet ray, an extreme ultraviolet ray, an X-ray, or the like represented by a bright-line spectrum of a mercury lamp and an excimer laser but also drawing with a corpuscular ray such as an electron beam and an ion beam, unless otherwise noted.

In the present specification, a numerical range expressed by using “to” means a range including the numerical values mentioned before and after “to” as the lower limit and the upper limit.

The bonding direction of a divalent group written in the present specification is not limited unless otherwise noted. For example, in a compound represented by a formula of “X—Y—Z”, when Y is —COO—, Y may be —CO—O— or may be —O—CO—. In addition, the compound may be “X—CO—O—Z” or may be “X—O—CO—Z”.

In the present specification, the weight average molecular weight (Mw), number average molecular weight (Mn), and dispersity (also referred to as molecular weight distribution) (Mw/Mn) of a resin are defined as polystyrene equivalent values by GPC (Gel Permeation Chromatography) measurement with a GPC apparatus (manufactured by TOSOH Corporation, HLC-8120 GPC) (solvent: tetrahydrofuran, flow rate (sample injection amount): 10 μL, column: manufactured by TOSOH Corporation, TSK gel Multipore HXL-M, column temperature: 40° C., flow rate: 1.0 mL/min, detector: differential refractive index detector).

In the present specification, the acid dissociation constant (pKa) represents the pKa in an aqueous solution and is, specifically, a value determined by calculation based on the Hammett's substituent constant and a database of known literature values using the software package 1 below. The pKa values described in the present specification are all values determined by calculation using this software package.

Software package 1: Advanced Chemistry Development (ACD/Labs) Software V8.14 for Solaris (1994-2007 ACD/Labs).

The pKa can also be determined by a molecular orbital calculation method. Examples of this method include an approach of calculating the pKa by computing the H⁺ dissociation free energy in an aqueous solution based on a thermodynamic cycle. Although the H⁺ dissociation free energy can be computed by, for example, a density functional theory (DFT), other various approaches have been reported in literature, and the approach is not limited thereto. There are multiple software that can implement the DFT, and examples thereof include Gaussian 16.

The pKa in the present specification refers to, as described above, a value determined by calculation based on the Hammett's substituent constant and a database of known literature values using the software package 1. However, when the pKa cannot be calculated by this approach, a value obtained by Gaussian 16 based on a density functional theory (DFT) is adopted.

The pKa in the present specification refers to, as described above, “pKa in an aqueous solution”. However, when the pKa in an aqueous solution cannot be calculated, “pKa in a dimethyl sulfoxide (DMSO) solution” is adopted.

In the present specification, examples of the halogen atom include a fluorine atom, a chlorine atom, a bromine atom, and an iodine atom.

In the present specification, the solid content means a component that forms a resist film and does not include a solvent. Any component that forms a resist film is considered as solid content even if it is in a liquid form.

### Active Light Ray Sensitive or Radioactive Ray Sensitive Resin Composition

The active light ray sensitive or radioactive ray sensitive resin composition (hereinafter, also referred to as “resist composition”) of the present invention is an active light ray sensitive or radioactive ray sensitive resin composition including:
a metal compound;
a resin having a main chain that is decomposed by irradiation with an X-ray, an electron beam, or an extreme ultraviolet ray; and
a solvent, wherein
the metal compound (hereinafter, also referred to as “specific metal compound”) includes one or more metal compounds selected from the group consisting of a metal complex, an organic metal salt, and an organic metal compound, and
the resin (hereinafter, also referred to as “specific resin”) includes a repeating unit represented by a formula (1) described later and a repeating unit represented by a formula (XR0) described later.

The resist composition of the present invention is excellent in sensitivity and can form a pattern with excellent resolution by the above-described configuration. Although the detail is not clear, the present inventors infer this as follows.

The specific resin includes a predetermined repeating unit and thereby decreases the molecular weight by cutting the main chain through irradiation with an X-ray, an electron beam, or an extreme ultraviolet ray to increase the solubility in developer. A resist film formed by a resist composition including the specific resin causes a difference of solubility in developer (dissolution contrast) between an exposed portion and an unexposed portion by being irradiated with an X-ray, an electron beam, or an extreme ultraviolet ray due to the mechanism of action of the specific resin, and thereby a pattern can be formed.

The resist film formed by the resist composition of the present invention includes a specific metal compound together with the above-described specific resin. Such a resist film, when irradiated with an X-ray, an electron beam, or an extreme ultraviolet ray, generates secondary electrons due to decomposition (ionization) of the specific resin and also generates secondary electrons from the specific metal compound. Accordingly, the amount of secondary electrons occurring in the film is significantly large. As a result of this, it is inferred that the decomposition amount of the main chain of the specific resin occurring due to the generated secondary electrons increases (in other words, the main chain decomposition efficiency is high), and the sensitivity is excellent.

The specific resin includes a relatively high-polar bond, such as a carbonyl bond and an ether bond, and may optionally include a relatively high-polar functional group (e.g., a hydroxy group, a carboxyl group, an amino group, an amide group, a thiol group, and an acetoxy group) as described later. In a resist film formed by the resist composition of the present invention, it is inferred that the specific metal compound is present in an aggregation structure formed by loose binding through the high-polar bond in the specific resin and electrostatic interaction with a functional group (a hetero atom or an atomic group including a hetero atom). At the same time, the aggregation structure is easily released by irradiation with an X-ray, an electron beam, or an extreme ultraviolet ray. That is, it is inferred that in the resist film formed by the resist composition of the present invention, the dissolution contrast between an unexposed portion and an exposed portion is high by the influence of electrostatic interaction between the specific metal compound and the specific resin, and as a result, the formed pattern has excellent resolution.

Hereinafter, higher sensitivity of the resist composition and/or higher resolution of a pattern formed from the resist composition is also referred to as “the effect of the present invention is more excellent”.

Each of components included in the resist composition will now be described.

### Specific Resin

The resist composition includes a resin (specific resin) including a repeating unit represented by a formula (1) described later or a repeating unit represented by a formula (XR) described later as the resin having a main chain that is decomposed by irradiation with an X-ray, an electron beam, or an extreme ultraviolet ray.

A specific aspect of the specific resin is preferably a resin (hereinafter, also referred to as “specific resin 1”) including a repeating unit represented by the formula (1) described later or a resin (hereinafter, also referred to as “specific resin 2”) including a repeating unit represented by the formula (XR) described later.

The specific resin may be a resin including both a repeating unit represented by the formula (1) described later and a repeating unit represented by the formula (XR) described later.

The specific resin preferably includes one or more functional groups (hereinafter, also referred to as “specific functional group”) selected from the group consisting of a hydroxy group (an alcoholic hydroxy group and a phenolic hydroxy group), a carboxyl group, an amino group, an amide group, a thiol group, and an acetoxy group in the point that the effect of the present invention is more excellent, as described later, and more preferably includes one or more functional groups selected from the group consisting of a phenolic hydroxy group and a carboxyl group.

The specific resin is preferably a specific resin 1 in the point that the effect of the present invention is excellent, more preferably a resin including a repeating unit represented by the formula (1) and a repeating unit represented by a formula (3), and further preferably a resin including a repeating unit represented by the formula (1) (where, X represents a chlorine atom) and a repeating unit represented by the formula (3) (where, C¹ represents a phenolic hydrogen atom or a carboxy group), in particular, in the point that the sensitivity is further improved.

The specific resin 1 and the specific resin 2 will now be respectively described.

### Specific Resin 1

The specific resin 1 is a resin including a repeating unit represented by the formula (1) below.

### Repeating Unit Represented by Formula (1)

A repeating unit represented by the formula (1) will now be described.

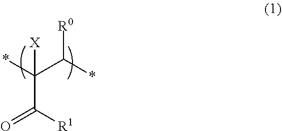

In the formula (1), X represents a halogen atom or a fluorinated alkyl group.

The halogen atom represented by X is preferably a chlorine atom in the point that the effect of the present invention is more excellent.

The alkyl group in the fluorinated alkyl group represented by X may be linear, branched, or cyclic. Although the number of fluorine atoms substituting for the alkyl group may be one or more, a perfluoroalkyl group is preferred in the point that the effect of the present invention is more excellent.

The number of carbon atoms of the fluorinated alkyl group represented by X is preferably 1 to 12, more preferably 1 to 6, and further preferably 1 to 3.

X is preferably a halogen atom and more preferably a chlorine atom in the point that the effect of the present invention is more excellent.

In the formula (1), R⁰ represents a hydrogen atom or an organic group.

The organic group represented by R⁰ is not particularly limited, but is preferably a linear, branched, or cyclic alkyl group.

The number of carbon atoms of the alkyl group is preferably 1 to 12, more preferably 1 to 6, and further preferably 1 to 3.

The alkyl group may have a substituent. The substituent is not particularly limited, but examples thereof include a halogen atom (preferably a fluorine atom or an iodine atom) and a specific functional group.

R⁰ is preferably a hydrogen atom in the point that the effect of the present invention is more excellent.

R¹ represents a substituent.

The substituent represented by R¹ is not particularly limited, and examples thereof include a group represented by the following formula (1-1), a hydroxy group, and —NH₂.

Formula (1-1): *-L^{1A}-R^{1A}.

In the formula (1-1), * represents a binding site.

In the formula (1-1), L^{1A} represents a single bond, —O—, or —N(R^{X})—.

R^{X} represents a hydrogen atom or an organic group.

The organic group represented by R^{X} is not particularly limited, but is, for example, preferably a linear, branched, or cyclic alkyl group.

The number of carbon atoms of the alkyl group is preferably 1 to 12, more preferably 1 to 6, and further preferably 1 to 3.

The alkyl group may have a substituent. The substituent is not particularly limited, but examples thereof include a halogen atom (preferably a fluorine atom or an iodine atom) and a specific functional group.

R^{X} is preferably a hydrogen atom in the point that the effect of the present invention is more excellent.

In the formula (1-1), R^{1A} represents a hydrogen atom or an organic group.

The organic group represented by R¹ is not particularly limited, but examples thereof include an alkyl group, an aryl group, an aralkyl group, and a group including an onium salt structure described later.

The alkyl group may be linear, branched, or cyclic.

The number of carbon atoms of the alkyl group is not particularly limited, and is, for example, 1 to 20.

In the alkyl groups, the number of carbon atoms of the linear or branched alkyl group is preferably 1 to 20, more preferably 1 to 10, and further preferably 1 to 6.

Among the alkyl groups, the cyclic alkyl group (cycloalkyl group) may be monocyclic or polycyclic. The number of carbon atoms of the cyclic alkyl group is not particularly limited, but is, for example, preferably 5 to 15 and more preferably 5 to 10. Examples of the cycloalkyl group include a monocyclic cycloalkyl group, such as a cyclopentyl group and a cyclohexyl group, and a polycyclic cycloalkyl group, such as a norbornyl group, a tetracyclodecanyl group, a tetracyclododecanyl group, and an adamantyl group.

The alkyl group may have a substituent. The substituent is not particularly limited, and examples thereof include a halogen atom (preferably a fluorine atom or an iodine atom) and a specific functional group.

As one aspect of the alkyl group, a group represented by —C(R^{X1})(R^{X2})(R^{X3}) is mentioned. R^{X1} to R^{X3} each independently represent a linear, branched, or cyclic alkyl group.

The number of carbon atoms of each of the alkyl groups represented by R^{X1} to R^{X3} is not particularly limited, and is, for example, 1 to 20. In the alkyl groups, the number of carbon atoms of the linear or branched alkyl group is preferably 1 to 20, more preferably 1 to 10, and further preferably 1 to 6. Among the alkyl groups, the cyclic alkyl group (cycloalkyl group) may be monocyclic or polycyclic. The number of carbon atoms of the cyclic alkyl group is not particularly limited, but is, for example, preferably 5 to 15 and more preferably 5 to 10. Examples of the cycloalkyl group include a monocyclic cycloalkyl group, such as a cyclopentyl group and a cyclohexyl group, and a polycyclic cycloalkyl group, such as a norbornyl group, a tetracyclodecanyl group, a tetracyclododecanyl group, and an adamantyl group.

It is preferable that R^{X1} to R^{X3} each independently represent a linear or branched alkyl group (preferably linear alkyl group) or that two of R^{X1} to R^{X3} are bound to each other to form a monocyclic or polycyclic 5- to 8-membered alicyclic ring.

The alkyl groups represented by R^{X1} to R^{X3} may have substituents. The substituent is not particularly limited, and examples thereof include a halogen atom (preferably a fluorine atom or an iodine atom) and a specific functional group.

When the alkyl group represents a group represented by —C(R^{X1})(R^{X2})(R^{X3}), L^{1A} preferably represents —O— or —N(R^{X})— and more preferably represents —O—.

The aryl group may be monocyclic or polycyclic and is preferably an aryl group having 6 to 20 carbon atoms, more preferably an aryl group having 6 to 15 carbon atoms, and further preferably an aryl group having 6 to 10 carbon atoms. In particular, the aryl group is preferably a phenyl group or a naphthyl group and more preferably a phenyl group.

The aryl group may have a substituent. The substituent is not particularly limited, and examples thereof include a halogen atom (preferably a fluorine atom or an iodine atom) and a specific functional group. In particular, a fluorine atom, an iodine atom, and a hydroxy group are preferred.

The aralkyl group is preferably a structure in which one of hydrogen atoms in the above-described alkyl group is substituted with the above-described aryl group. The number of carbon atoms of the aralkyl group is preferably 7 to 20 and more preferably 7 to 15.

The group including an onium salt structure is as described later.

In the formula (1), R⁰ and R¹ may be linked to each other to form a ring.

The ring formed by linking R⁰ and R¹ to each other is a ring that at least includes two carbon atoms and one carbonyl (>C═O) carbon atom specified in the formula (1) and is preferably a 5- to 8-membered ring and more preferably a 5- or 6-membered ring.

The ring may include a hetero atom (e.g., a nitrogen atom, an oxygen atom, or a sulfur atom) as a ring member atom. A carbon atom other than the carbon atoms (excluding two carbon atoms specified in the formula (1)) in the ring may be substituted with a carbonyl (>C═O) carbon atom.

As the repeating unit represented by the above-described formula (1), in the point that the effect of the present invention is more excellent, particularly, the repeating unit is preferably represented by the following formula (1A).

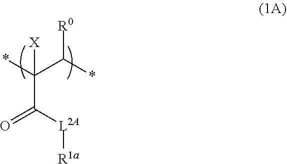

In the formula (1A), X and R⁰ are synonymous with X and R⁰ in the formula (1), and a preferable aspect is also the same.

In the formula (1A), L^{2A} represents —O— or —N(R^{X})—. R^{X} represents a hydrogen atom or an organic group. Examples of the organic group represented by R^{X} include those represented by R^{X} in the above-described formula (1-1).

In the formula (1A), R^{1A} represents a hydrogen atom or an organic group. Examples of the organic group represented by R^{1A} include those represented by R^{1A} in the above-described formula (1-1).

R⁰ and R^{1A} may be linked to each other to form a ring. Examples of the ring formed by linking R⁰ and R^{1A} to each other include the same rings as those formed by linking R⁰ and R¹ in the above-described formula (1).

In the specific resin 1, the content of the repeating unit represented by the formula (1) is preferably 5 to 95 mol %, more preferably 10 to 90 mol %, and further preferably 20 to 80 mol % relative to the total repeating units of the specific resin 1.

In the specific resin 1, the repeating unit represented by the formula (1) may be composed of one type or two or more types. When the repeating unit represented by the formula (1) is composed of two or more types, the total content is preferably in the above numerical range.

### Other Repeating Unit

The specific resin 1 preferably further includes another repeating unit (hereinafter, also referred to as “other repeating unit”) that is different from the repeating unit represented by the formula (1).

The other repeating unit is preferably a repeating unit represented by a formula (2) and is more preferably a repeating unit represented by the formula (3), in the point that the effect of the present invention is more excellent.

### Repeating Unit Represented by Formula (2)

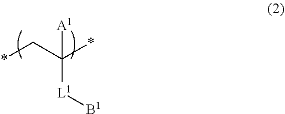

In the formula (2), A¹ represents a hydrogen atom or an alkyl group.

The alkyl group represented by A¹ may be linear, branched, or cyclic. The number of carbon atoms of the alkyl group is preferably 1 to 12, more preferably 1 to 6, and further preferably 1 to 3.

The alkyl group may have a substituent. The substituent is not particularly limited, but examples thereof include a halogen atom (preferably a fluorine atom or an iodine atom) and a specific functional group.

A¹ is, in the point that the effect of the present invention is more excellent, preferably an alkyl group, more preferably an alkyl group having 1 to 6 carbon atoms, and further preferably an alkyl group having 1 to 3 carbon atoms.

L¹ represents a single bond or a divalent linker group.

The divalent linker group represented by L¹ is not particularly limited, but examples thereof include —CO—, —O—, —SO—, —SO₂—, —NR^{A}—, an alkylene group (preferably having 1 to 6 carbon atoms, which may be linear or branched), a cycloalkylene group (preferably having 3 to 15 carbon atoms), and an arylene group (preferably a 6- to 10-membered ring and further preferably a 6-membered ring) and a divalent linker group of a combination of multiple of these examples. The alkylene group, the cycloalkylene group, and the arylene group may have substituents. Examples of the substituent include an alkyl group, a halogen atom, and a specific functional group. Examples of R^{A} include a hydrogen atom and an alkyl group having 1 to 6 carbon atoms.

L¹ is preferably a single bond, —COO—, or —CONR^{A}—.

B¹ represents a substituent.

The substituent represented by B¹ is not particularly limited, and examples thereof include an alkyl group, a cycloalkyl group, an aryl group, an aralkyl group, an alkenyl group, an alkoxy group, an acyloxy group, a cyano group, a nitro group, a halogen atom, a lactone group, a group including an onium salt structure described later, and a specific functional group.

The alkyl group, the cycloalkyl group, the aryl group, the aralkyl group, the alkenyl group, the alkoxy group, the acyloxy group, and the lactone group may further have substituents, and examples of the substituent include a halogen atom and a specific functional group. When the alkyl group has a fluorine atom, the alkyl group may be a perfluoroalkyl group.

The alkyl group may be linear or branched. The number of carbon atoms is not particularly limited, but is, for example, preferably 1 to 20, more preferably 1 to 10, and further preferably 1 to 6.

The cycloalkyl group may be monocyclic or polycyclic. The number of carbon atoms is not particularly limited, but is, for example, preferably 5 to 15 and more preferably 5 to 10. Examples of the cycloalkyl group include a monocyclic cycloalkyl group, such as a cyclopentyl group and a cyclohexyl group, and a polycyclic cycloalkyl group, such as a norbornyl group, a tetracyclodecanyl group, a tetracyclododecanyl group, and an adamantyl group.

The aryl group may be monocyclic or polycyclic. The number of carbon atoms is not particularly limited, but is, for example, preferably 6 to 15 and more preferably 6 to 10. The aryl group is preferably a phenyl group, a naphthyl group, or an anthranil group and more preferably a phenyl group.

The aralkyl group preferably has a structure in which one of hydrogen atoms in the above-described alkyl group is substituted with the above-described aryl group. The number of carbon atoms of the aralkyl group is preferably 7 to 20 and more preferably 7 to 15.

The alkenyl group may be linear, branched, or cyclic. The number of carbon atoms is not particularly limited, but is, for example, preferably 2 to 20, more preferably 2 to 10, and further preferably 2 to 6.

The alkoxy group may be linear, branched, or cyclic, and the number of carbon atoms is preferably 1 to 20, more preferably 1 to 10, and further preferably 1 to 6.

The acyloxy group may be linear, branched, or cyclic, and the number of carbon atoms is preferably 2 to 20, more preferably 2 to 10, and further preferably 2 to 6.

The lactone group is preferably a 5- to 7-membered ring lactone group and is more preferably one in which another ring structure is condensed with the lactone ring of a 5- to 7-membered ring to form a bicyclo structure or a spiro structure.

### Repeating Unit Represented by Formula (3)

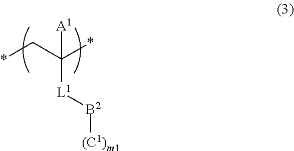

In the formula (3), A¹ and L¹ are synonymous with A¹ and L¹ in the formula (2), and a preferable aspect is also the same.

B² represents an (m1+1)-valent linker group.

Examples of the (m1+1)-valent linker group represented by B² include groups each formed by removing m1 hydrogen atoms from a monovalent group selected from the group consisting of an alkyl group, a cycloalkyl group, an aryl group, an aralkyl group, an alkenyl group, an alkoxy group, an acyloxy group, and a lactone group.

The alkyl group, the cycloalkyl group, the aryl group, the aralkyl group, the alkenyl group, the alkoxy group, the acyloxy group, and the lactone group may further have a substituent other than the functional group of a specific type represented by C¹, and examples of the substituent include a halogen atom. When the alkyl group has a fluorine atom, the alkyl group may be a perfluoroalkyl group.

The alkyl group may be linear or branched. The number of carbon atoms is not particularly limited, but is, for example, preferably 1 to 20, more preferably 1 to 10, and further preferably 1 to 6.

The cycloalkyl group may be monocyclic or polycyclic. The number of carbon atoms is not particularly limited, but is, for example, preferably 5 to 15 and more preferably 5 to 10. Examples of the cycloalkyl group include a monocyclic cycloalkyl group, such as a cyclopentyl group and a cyclohexyl group, and a polycyclic cycloalkyl group, such as a norbornyl group, a tetracyclodecanyl group, a tetracyclododecanyl group, and an adamantyl group.

The aryl group may be monocyclic or polycyclic. The number of carbon atoms is not particularly limited, but is, for example, preferably 6 to 15 and more preferably 6 to 10. The aryl group is preferably a phenyl group, a naphthyl group, or an anthranil group and more preferably a phenyl group.

The aralkyl group preferably has a structure in which one of hydrogen atoms in the above-described alkyl group is substituted with the above-described aryl group. The number of carbon atoms of the aralkyl group is preferably 7 to 20 and more preferably 7 to 15.

The alkenyl group may be linear, branched, or cyclic. The number of carbon atoms is not particularly limited, but is, for example, preferably 2 to 20, more preferably 2 to 10, and further preferably 2 to 6.

The alkoxy group may be linear, branched, or cyclic, and the number of carbon atoms is preferably 1 to 20, more preferably 1 to 10, and further preferably 1 to 6.

The acyloxy group may be linear, branched, or cyclic, and the number of carbon atoms is preferably 2 to 20, more preferably 2 to 10, and further preferably 2 to 6.

The lactone group is preferably the lactone group of a 5- to 7-membered ring and is more preferably one in which another ring structure is condensed with the lactone ring of a 5- to 7-membered ring to form a bicyclo structure or a spiro structure.

The (m1+1)-valent linker group represented by B² is, in particular, preferably an (m1+1)-valent aromatic hydrocarbon ring group (a group formed by removing m1 hydrogen atoms from an aryl group) and more preferably an (m1+1)-valent benzene ring group or an (m1+1)-valent naphthalene ring group. The (m1+1)-valent benzene ring group and the (m1+1)-valent naphthalene ring group may preferably have a halogen atom as a substituent.

C¹ represents one or more functional groups selected from the group consisting of a hydroxy group, a carboxyl group, an amino group, an amide group, a thiol group, and an acetoxy group. That is, C¹ represents a specific functional group. The functional group is more preferably one or more functional groups selected from the group consisting of a phenolic hydroxy group and a carboxyl group, in the point that the effect of the present invention is more excellent.

When C¹ represents a phenolic hydroxy group, the (m1+1)-valent linker group represented by B¹ is preferably an (m1+1)-valent aromatic hydrocarbon ring group (a group formed by removing m1 hydrogen atoms from an aryl group).
m1 represents an integer of 1 or more.
m1 is, for example, preferably 1 to 6 and more preferably 1 to 3.

When m1 represents an integer of 2 or more, a plurality of C¹'s may be the same or different.

In the specific resin 1, the content of the repeating unit represented by the formula (2) (preferably the repeating unit represented by the formula (3)) is preferably 5 to 95 mol %, more preferably 10 to 90 mol %, and further preferably 20 to 80 mol %, relative to the total repeating units of the specific resin 1.

In the specific resin 1, the repeating unit represented by the formula (2) (preferably the repeating unit represented by the formula (3)) may be composed of one type or two or more types. When the repeating unit represented by the formula (2) (preferably the repeating unit represented by the formula (3)) is composed of two or more types, the total content is preferably in the above numerical range.

### Preferable Aspect of Specific Resin 1

The specific resin 1 preferably includes a repeating unit represented by the formula (1) and a repeating unit represented by the formula (2) and more preferably includes a repeating unit represented by the formula (1) and a repeating unit represented by the formula (3).

The total content of the repeating unit represented by the formula (1) and the repeating unit represented by the formula (2) (preferably the repeating unit represented by the formula (3)) is preferably 90 mol % or more and more preferably 95 mol % or more relative to the total repeating units of the specific resin 1. The upper limit is preferably 100 mol % or less.

When the specific resin 1 is a copolymer including a repeating unit represented by the formula (1) and a repeating unit represented by the formula (2) (preferably a repeating unit represented by the formula (3)), the copolymer may be in any form, such as a random copolymer, a block copolymer, or an alternating copolymer (a copolymer in which a repeating unit represented by the formula (1) and a repeating unit represented by the formula (2) (preferably a repeating unit represented by the formula (3)) are arranged alternately such as ABAB . . . ), and is, in particular, preferably an alternating copolymer.

As a preferable aspect of the specific resin 1, an aspect in which the proportion of the alternating copolymer present in the specific resin 1 is 90 mass % or more (preferably 100 mass %) relative to the total mass of the specific resin 1 is also included.

### Group Including Onium Salt Structure

The group including an onium salt structure that can be included in the specific resin 1 will now be described.

The onium salt structure is a structural site having an ion pair of a cation and an anion and is preferably a structural site represented by “Xⁿ⁻nM⁺” (n represents, for example, an integer of 1 to 3 and preferably represents 1 or 2).

M⁺ is a structural site including a positively charged atom or atomic group, and Xⁿ⁻ represents a structural site including a negatively charged atom or atomic group. The anion in the onium salt group is preferably a non-nucleophilic anion (an anion with extremely low ability to cause a nucleophilic reaction). When the anion in the onium salt group is a non-nucleophilic anion, it is likely to be a photodegradable onium salt structure. Examples of the non-nucleophilic anion include non-nucleophilic anions that are described as generated acids of the photodegradable onium salt compound described later.

The group including an onium salt structure is preferably a group represented by the following formula (O1):

*-L_{T}-X_{A}⁻M_{A}⁺ formula (01).

In the formula (01), L_{T} represents a single bond or a divalent linker group. Examples of the divalent linker group represented by L_{T} include the same divalent linker groups as those represented by L¹ in the formula (2). X_{A}⁻ represents a monovalent organic anionic group. M_{A}⁺ represents an organic cation.

The monovalent organic anionic group represented by X_{A}⁻ is preferably a non-nucleophilic anionic group (an anionic group with extremely low ability to cause a nucleophilic reaction).

In the formula (01), the monovalent anionic group represented by X_{A}⁻ is not particularly limited, but is, for example, preferably a group selected from the group consisting of groups represented by the following formulae (B-1) to (B-14).

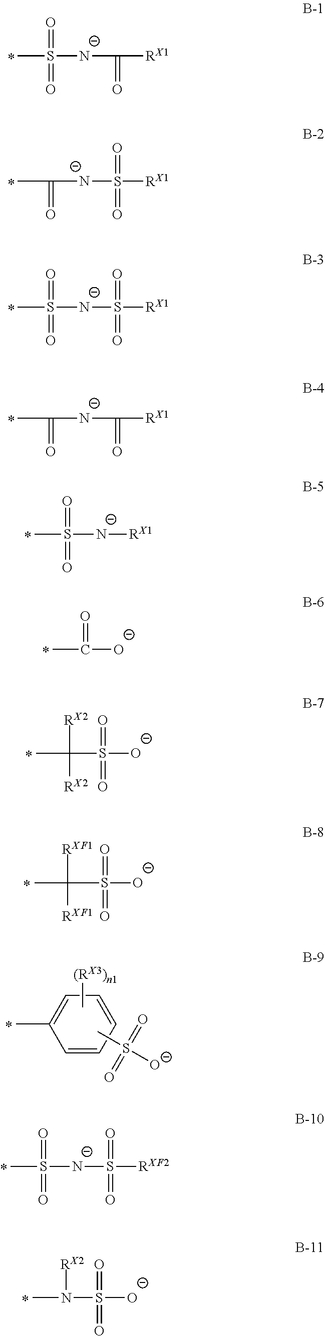

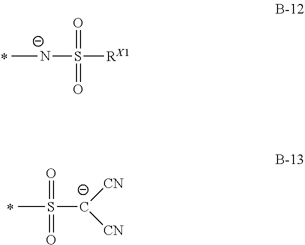

*—O⁻ formula (B-14).

In the formulae (B-1) to (B-14), * represents a binding site.

In the formulae (B-1) to (B-5) and formula (B-12), R^{X1}s each independently represent a monovalent organic group.

In the formulae (B-7) and formula (B-11), R^{X2}'s each independently represent a hydrogen atom or a substituent other than a fluorine atom and a perfluoroalkyl group. Two R^{X2}'s in the formula (B-7) may be the same or different.

In the formula (B-8), R^{XF1} represents a hydrogen atom, a fluorine atom, or a perfluoroalkyl group. However, at least one of two R^{XF1}'s represents a fluorine atom or a perfluoroalkyl group. Two R^{XF1}'s in the formula (B-8) may be the same or different.

In the formula (B-9), R^{X3} represents a hydrogen atom, a halogen atom, or a monovalent organic group, and n1 represents an integer of 0 to 4. When n1 represents an integer of 2 to 4, a plurality of R^{X3}'s may be the same or different.

In the formula (B-10), R^{XF2} represents a fluorine atom or a perfluoroalkyl group.

A partner that binds to the binding site represented by * of the formula (B-14) is preferably a phenylene group that may have a substituent. Examples of the substituent that the phenylene group may have include a halogen atom.

In the formulae (B-1) to (B-5) and formula (B-12), R^{X1}'s each independently represent a monovalent organic group.

R^{X1} is preferably an alkyl group (it may be linear or branched, and the number of carbon atoms is preferably 1 to 15), a cycloalkyl group (it may be monocyclic or polycyclic, and the number of carbon atoms is preferably 3 to 20), or an aryl group (it may be monocyclic or polycyclic, and the number of carbon atoms is preferably 6 to 20). The group represented by R^{X1} may have a substituent.

In the formula (B-5), in R^{X1}, the atom that directly binds to N— is preferably other than the carbon atom of —CO— and the sulfur atom of —SO₂—.

The cycloalkyl group in R^{X1} may be monocyclic or polycyclic.

Examples of the cycloalkyl group in R^{X1} include a norbornyl group and an adamantyl group.

The substituent that the cycloalkyl group in R^{X1} may have is not particularly limited, but is preferably an alkyl group (it may be linear or branched, and the number of carbon atoms is preferably 1 to 5). One or more of the carbon atoms that are the ring member atoms of the cycloalkyl group in R^{X1} may be replaced by a carbonyl carbon atom.

The number of carbon atoms of the (linear or branched) alkyl group in R^{X1} is preferably 1 to 10 and more preferably 1 to 5.

The substituent that the alkyl group in R^{X1} may have is not particularly limited, but is, for example, preferably a cycloalkyl group, a fluorine atom, or a cyano group.

Examples of the cycloalkyl group as the substituent include the same cycloalkyl groups as those when R^{X1} is a cycloalkyl group.

When the alkyl group in R^{X1} has a fluorine atom as the substituent, the alkyl group may be a perfluoroalkyl group.

In the alkyl group in R^{X1}, one or more —CH₂— may be substituted with a carbonyl group.

The aryl group in R^{X1} is preferably a benzene ring group.

The substituent that the aryl group in R^{X1} may have is not particularly limited, but is preferably an alkyl group, a fluorine atom, or a cyano group. Examples of the alkyl group as the substituent include the same alkyl groups as those when R^{X1} is an alkyl group.

In the formulae (B-7) and (B-11), R^{X2}'s each independently represent a hydrogen atom or a substituent other than a fluorine atom and a perfluoroalkyl group (examples thereof include an alkyl group (it may be linear or branched, and the number of carbon atoms is preferably 1 to 15) not including a fluorine atom and a cycloalkyl group (it may be monocyclic or polycyclic, and the number of carbon atoms is preferably 3 to 20) not including a fluorine atom). Two R^{X2}'s in the formula (B-7) may be the same or different.

In the formula (B-8), R^{XF1} represents a hydrogen atom, a fluorine atom, or a perfluoroalkyl group. However, at least one of a plurality of R^{XF1}'s represents a fluorine atom or a perfluoroalkyl group. Two R^{XF1}'s in the formula (B-8) may be the same or different. The number of carbon atoms of the perfluoroalkyl group represented by R^{XF1} is preferably 1 to 15, more preferably 1 to 10, and further preferably 1 to 6.

In the formula (B-9), R^{X3} represents a hydrogen atom, a halogen atom, or a monovalent organic group. Examples of the halogen atom as R^{X3} include a fluorine atom, a chlorine atom, a bromine atom, and an iodine atom, and, in particular, a fluorine atom is preferable.

The monovalent organic groups as R^{X3} are the same as the monovalent organic groups described as R^{X1}.

n1 is an integer of 0 to 4.

n1 is preferably an integer of 0 to 2 and preferably 0 or 1. When n1 represents an integer of 2 to 4, a plurality of R^{X3}'s may be the same or different.

In the formula (B-10), R^{XF2} represents a fluorine atom or a perfluoroalkyl group.

The number of carbon atoms of the perfluoroalkyl group represented by R^{XF2} is preferably 1 to 15, more preferably 1 to 10, and further preferably 1 to 6.

The organic cation represented by M_{A}⁺ in the formula (01) is preferably an organic cation (cation (ZaI)) represented by a formula (ZaI) or an organic cation (cation (ZaII)) represented by a formula (ZaII).

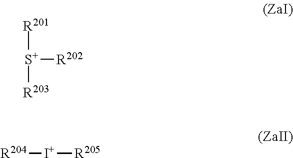

In the formula (ZaI),

R²⁰¹, R²⁰², and R²⁰³ each independently represent an organic group.

The number of carbon atoms of the organic group as R²⁰¹, R²⁰², or R²⁰³ is generally 1 to 30 and preferably 1 to 20. Two of R²⁰¹ to R²⁰³ may be bound to each other to form a ring structure, and the ring may include therein an oxygen atom, a sulfur atom, an ester group, an amide group, or a carbonyl group. Examples of the group that is formed by binding of two of R²⁰¹ to R²⁰³ include an alkylene group (e.g., a butylene group and a pentylene group) and —CH₂—CH₂—O—CH₂—CH₂—.

Examples of the preferable aspect of the organic cation in the formula (ZaI) include a cation (ZaI-1), a cation (ZaI-2), an organic cation (cation (ZaI-3b)) represented by a formula (ZaI-3b), and an organic cation (cation (ZaI-4b)) represented by a formula (ZaI-4b), described later.

The cation (ZaI-1) will be first described.

The cation (ZaI-1) is an arylsulfonium cation in which at least one of R²⁰¹ to R²⁰³ of the formula (ZaI) is an aryl group.

In the arylsulfonium cation, all of R²⁰¹ to R²⁰³ may be an aryl group; or a part of R²⁰¹ to R²⁰³ may be an aryl group, and the remainder may be an alkyl group or a cycloalkyl group.

Alternatively, one of R²⁰¹ to R²⁰³ may be an aryl group, and the remaining two of R²⁰¹ to R²⁰³ may be bound to each other to form a ring structure, and the ring may include therein an oxygen atom, a sulfur atom, an ester group, an amide group, or a carbonyl group. Examples of the group that is formed by binding of two of R²⁰¹ to R²⁰³ include an alkylene group in which one or more methylene groups may be substituted with an oxygen atom, a sulfur atom, an ester group, an amide group, and/or a carbonyl group (e.g., a butylene group, a pentylene group, or —CH₂—CH₂—O—CH₂—CH₂—).

Examples of the arylsulfonium cation include a triarylsulfonium cation, a diarylalkylsulfonium cation, an aryldialkylsulfonium cation, a diarylcycloalkylsulfonium cation, and an aryldicycloalkylsulfonium cation.

The aryl group included in the arylsulfonium cation is preferably a phenyl group or a naphthyl group and more preferably a phenyl group. The aryl group may be an aryl group having a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. When the arylsulfonium cation has two or more aryl groups, the two or more aryl groups may be the same or different.

The alkyl group or cycloalkyl group that the arylsulfonium cation has as needed is preferably a linear alkyl group having 1 to 15 carbon atoms, a branched alkyl group having 3 to 15 carbon atoms, or a cycloalkyl group having 3 to 15 carbon atoms and more preferably, for example, a methyl group, an ethyl group, a propyl group, an n-butyl group, a sec-butyl group, a t-butyl group, a cyclopropyl group, a cyclobutyl group, and a cyclohexyl group.

The substituents that the aryl group, alkyl group, and cycloalkyl group of R²⁰¹ to R²⁰³ may have are each independently preferably an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a cycloalkylalkoxy group (having, for example, 1 to 15 carbon atoms), a halogen atom (for example, fluorine or iodine), a hydroxy group, a carboxyl group, an ester group, a sulfinyl group, a sulfonyl group, an alkylthio group, or a phenylthio group.

The substituent may further have a substituent when it is possible. For example, it is also preferable that the alkyl group has a halogen atom as a substituent and becomes a halogenated alkyl group such as a trifluoromethyl group.

Then, the cation (ZaI-2) will be described.

The cation (ZaI-2) is a cation in which R²⁰¹ to R²⁰³ in the formula (ZaI) each independently represent an organic group not having an aromatic ring. Here, the aromatic ring encompasses an aromatic ring including a hetero atom.

The organic group not having an aromatic ring as R²⁰¹ to R²⁰³ has generally 1 to 30 carbon atoms and preferably 1 to 20 carbon atoms.

R²⁰¹ to R²⁰³ are preferably each independently an alkyl group, a cycloalkyl group, an aryl group, or a vinyl group, more preferably a linear or branched 2-oxoalkyl group, a 2-oxocycloalkyl group, or an alkoxycarbonylmethyl group, and further preferably a linear or branched 2-oxoalkyl group.

Examples of the alkyl group and cycloalkyl group of R²⁰¹ to R²⁰³ include a linear alkyl group having 1 to 10 carbon atoms or a branched alkyl group having 3 to 10 carbon atoms (e.g., a methyl group, an ethyl group, a propyl group, a butyl group, and a pentyl group) and a cycloalkyl group having 3 to 10 carbon atoms (e.g., a cyclopentyl group, a cyclohexyl group, and a norbornyl group).

R²⁰¹ to R²⁰³ may be further substituted with a halogen atom, an alkoxy group (having, for example, 1 to 5 carbon atoms), a hydroxy group, a cyano group, or a nitro group.

Then, the cation (ZaI-3b) will be described.

The cation (ZaI-3b) is a cation represented by the following formula (ZaI-3b).

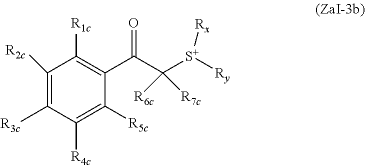

In the formula (ZaI-3b),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxy group, a nitro group, an alkylthio group, or an arylthio group.

R_{6c} and R_{7c} each independently represent a hydrogen atom, an alkyl group (such as a t-butyl group), a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an aryl group, or a vinyl group.

Two or more of R_{1c} to R_{5c}, R_{5c} and R_{6c}, R_{6c} and R_{7c}, R_{5c} and Rₓ, or Rₓ and R_{y} may be bound to each other to form a ring, and these rings may each independently include an oxygen atom, a sulfur atom, a ketone group, an ester bond, or an amide bond.

Examples of the ring include an aromatic or nonaromatic hydrocarbon ring, an aromatic or nonaromatic hetero ring, and a polycyclic fused ring composed of a combination of two or more of these rings. Examples of the ring include 3- to 10-membered rings, and 4- to 8-membered rings are preferable, and a 5- or 6-membered ring is more preferable.

Examples of the group that is formed by binding two or more of R_{1c} to R_{5c}, R_{6c} and R_{7c}, or Rₓ and R_{y} include an alkylene group, such as a butylene group and a pentylene group. The methylene group in this alkylene group may be substituted with a hetero atom such as an oxygen atom.

The group that is formed by binding R_{5c} and R_{6c} or R_{5c} and Rₓ is preferably a single bond or an alkylene group. Examples of the alkylene group include a methylene group and an ethylene group.

The ring formed by binding two or more of R_{1c} to R_{5c}, R_{6c}, R_{7c}, Rₓ, R_{y}, and R_{1c} to R_{5c}, or R_{5c} and Roc, Roc and R_{7c}, R_{5c} and Rₓ, or Rₓ and R_{y} to each other may have a substituent.

Then, the cation (ZaI-4b) will be described.

The cation (ZaI-4b) is a cation represented by the following formula (ZaI-4b).

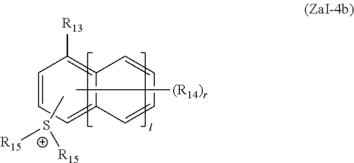

In the formula (ZaI-4b),

l represents an integer of 0 to 2.

r represents an integer of 0 to 8.

R₁₃ represents a hydrogen atom, a halogen atom (e.g., a fluorine atom or an iodine atom), a hydroxy group, an alkyl group, a halogenated alkyl group, an alkoxy group, a carboxyl group, an alkoxycarbonyl group, or a group having a cycloalkyl group (which may be a cycloalkyl group itself or a group partially including a cycloalkyl group). These groups may have substituents.

R₁₄ represents a hydroxy group, a halogen atom (e.g., a fluorine atom or an iodine atom), an alkyl group, a halogenated alkyl group, an alkoxy group, an alkoxycarbonyl group, an alkylcarbonyl group, an alkylsulfonyl group, a cycloalkylsulfonyl group, or a group having a cycloalkyl group (which may be a cycloalkyl group itself or a group partially including a cycloalkyl group). These groups may have substituents. When a plurality of R₁₄'s is represent, they each independently represent the above-mentioned groups such as a hydroxy group.

R₁₅'s each independently represent an alkyl group, cycloalkyl group or a naphthyl group. Two R₁₅'s may be bound to each other to form a ring. When two R₁₅'s are bound to each other to form a ring, the ring skeleton may include therein a hetero atom such as an oxygen atom or a nitrogen atom. In one aspect, two R₁₅'s are preferably alkylene groups and are bound to each other to form a ring structure. The alkyl group, the cycloalkyl group, the naphthyl group, and the ring formed by binding two R₁₅'s to each other may have substituents.

In the formula (ZaI-4b), the alkyl group of R₁₃, R₁₄, and R₁₅ is preferably linear or branched. The number of carbon atoms of the alkyl group is preferably 1 to 10. The alkyl group is more preferably a methyl group, an ethyl group, an n-butyl group, or a t-butyl group.

Then, the formula (ZaII) will be described.

In the formula (ZaII), R²⁰⁴ and R²⁰⁵ each independently represent an aryl group, an alkyl group, or a cycloalkyl group.

The aryl group of R²⁰⁴ and R²⁰⁵ is preferably a phenyl group or a naphthyl group and more preferably a phenyl group. The aryl group of R²⁰⁴ and R²⁰⁵ may be an aryl group having a hetero ring having an oxygen atom, a nitrogen atom, a sulfur atom, or the like. Examples of the skeleton of the aryl group having a hetero ring include pyrrole, furan, thiophene, indole, benzofuran, and benzothiophene.

The alkyl group and cycloalkyl group of R²⁰⁴ and R²⁰⁵ are preferably a linear alkyl group having 1 to 10 carbon atoms or a branched alkyl group having 3 to 10 carbon atoms (e.g., a methyl group, an ethyl group, a propyl group, a butyl group, and a pentyl group) or a cycloalkyl group having 3 to 10 carbon atoms (e.g., a cyclopentyl group, a cyclohexyl group, and a norbornyl group).

The aryl group, alkyl group, and cycloalkyl group of R²⁰⁴ and R²⁰⁵ may each independently have a substituent. Examples of the substituent that the aryl group, alkyl group, and cycloalkyl group of R²⁰⁴ and R²⁰⁵ may have include an alkyl group (having, for example, 1 to 15 carbon atoms), a cycloalkyl group (having, for example, 3 to 15 carbon atoms), an aryl group (having, for example, 6 to 15 carbon atoms), an alkoxy group (having, for example, 1 to 15 carbon atoms), a halogen atom, a hydroxy group, and a phenylthio group.

Examples of the organic cation are shown below, but the present invention is not limited thereto.

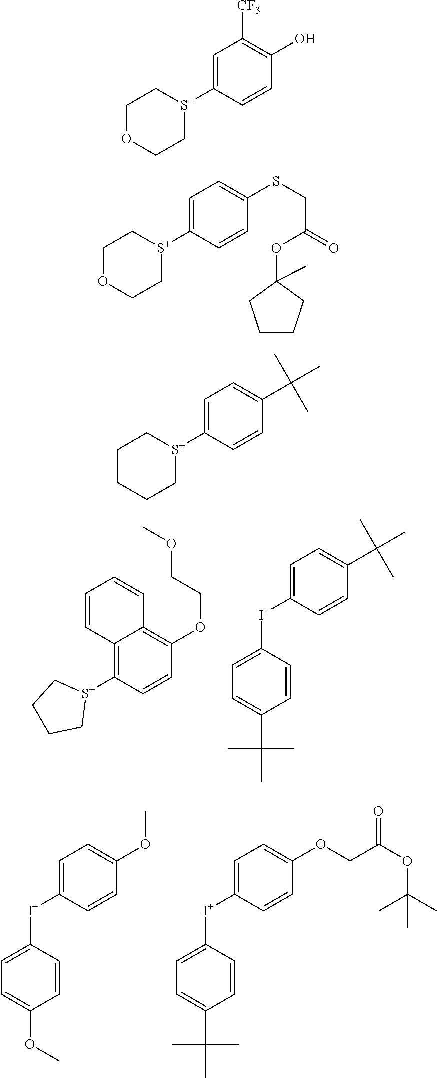

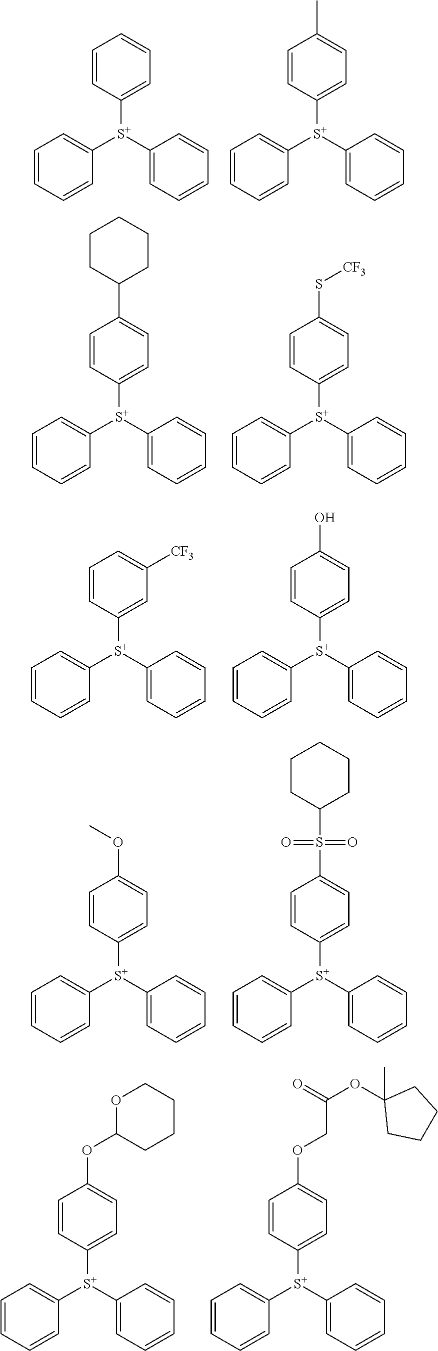

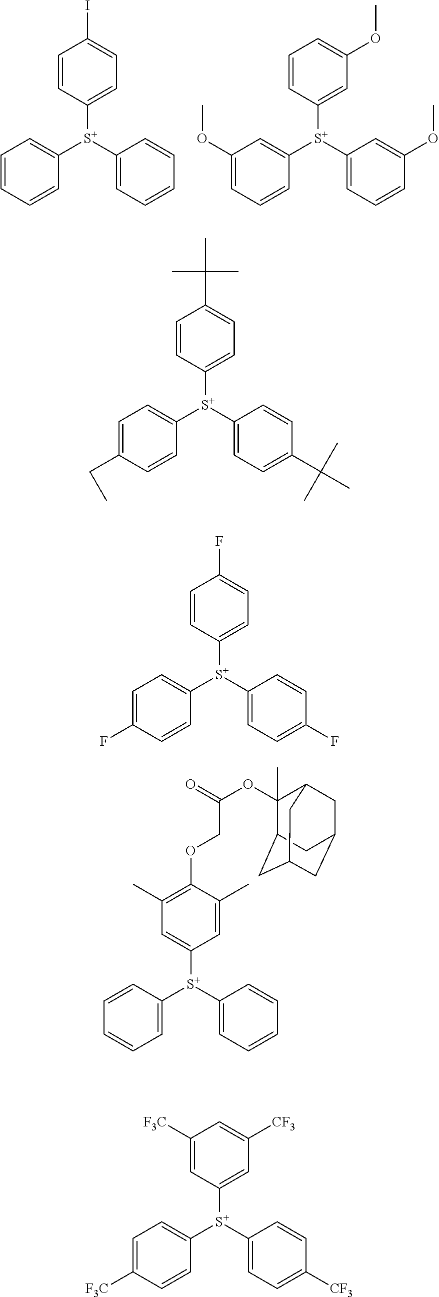 [SMILES: Ic1ccc([S+](c2ccccc2)c2ccccc2)cc1 ; COc1cccc([S+](c2cccc(OC)c2)c2cccc(OC)c2)c1 ; CCc1ccc([S+](c2ccc(C(C)(C)C)cc2)c2ccc(C(C)(C)C)cc2)cc1 ; Fc1ccc([S+](c2ccc(F)cc2)c2ccc(F)cc2)cc1 ; Cc1cc([S+](c2ccccc2)c2ccccc2)cc(C)c1OCC(=O)OC1(C)C2CC3CC(C2)CC1C3 ; FC(F)(F)c1ccc([S+](c2ccc(C(F)(F)F)cc2)c2cc(C(F)(F)F)cc(C(F)(F)F)c2)cc1]

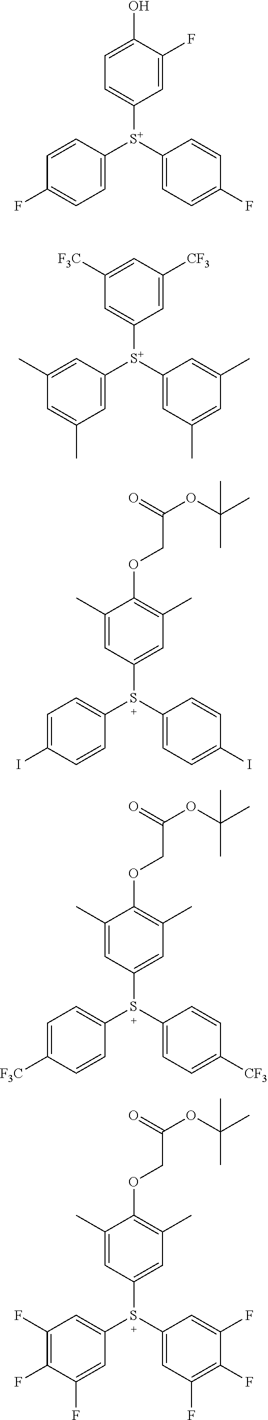

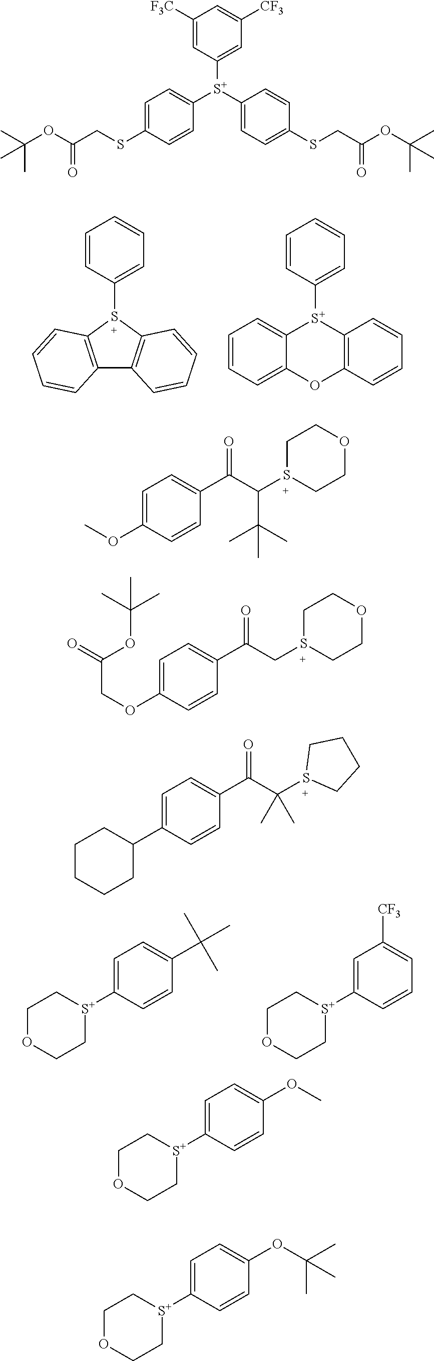

### Specific Resin 2

The specific resin 2 is a resin including a repeating unit represented by the following formula (XR).

### Repeating Unit Represented by Formula (XR)

The repeating unit represented by the formula (XR) will now be described.

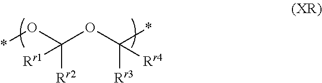

In the formula (XR), R^{r1} to R^{r4} each independently represent a hydrogen atom or a substituent. R^{r2} and R^{r3} may be bound to each other to form a ring. * represents a binding site.

The specific resin 2 preferably has the above-described specific functional group.

As the specific resin 2, it is preferable that at least one or more of R^{r1} to R^{r4} in the formula (XR) represent substituents and at least one or more of the substituents have the above-described specific functional group, that R^{r2} and R^{r3} in the formula (XR) are bound to each other to form a ring and at least one or more of substituents substituted on this ring have the above-described specific functional group, or that a repeating unit other than the repeating unit represented by the formula (XR) is included and this additional repeating unit has the above-described specific functional group.

As the specific resin 2, it is more preferable that at least one or more of R^{r1} to R^{r4} in the formula (XR) represent substituents and at least one or more of the substituents have the above-described specific functional group, or that R^{r2} and R^{r3} in the formula (XR) are bound to each other to form a ring and at least one or more of substituents substituted on this ring have the above-described specific functional group.

In the point that the effect of the present invention is more excellent, as the specific resin 2, it is more preferable that R^{r2} and R^{r3} in the formula (XR) are bound to each other to form a ring and at least one or more of substituents substituted on the ring have the above-described specific functional group.

### Suitable Form of Specific Resin 2

A suitable form of the specific resin 2 will now be described in detail.

In the specific resin 2, the repeating unit represented by the formula (XR) is preferably 90 mol % or more and more preferably 95 mol % or more relative to the total repeating units of the specific resin 2. The upper limit is preferably 100 mol % or less.

In the formula (XR), examples of the substituents represented by R^{r1} to R^{r4} include the same substituents as those represented by B¹ in the above-described formula (2), and a preferable aspect is also the same.

As one aspect of the substituent represented by R^{r1} to R^{r4}, an aspect represented by *-L_{N}-RpA is also preferable. L_{N} represents a single bond or a divalent linker group. Examples of the divalent linker group represented by L_{N} include the same divalent linker groups as those represented by L¹ in the above-described formula (2). R^{pA} represents a specific functional group.

In the formula (XR), the ring that is formed by binding R^{r2} and R^{r3} to each other is not particularly limited and may be an alicyclic ring or an aromatic ring. The ring may further have a substituent. Examples of the substituent include the same substituents represented by R^{r1} to R^{r4}.

In the formula (XR), when R^{r2} and R^{r3} are bound to each other, it is also preferable that the repeating unit represented by the formula (XR) is a repeating unit represented by the following formula (XRA).

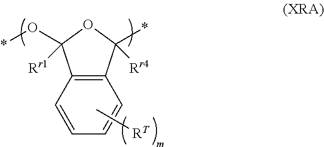

In the formula, R^{r1} and R^{r4} are synonymous with R^{r1} and R^{r4} in the formula (XR), and a preferable aspect is also the same. R^{T} represents a substituent. Examples of the substituent represented by R^{T} include the same substituents as those represented by R^{r1} to R^{r4}. At least one of the substituents represented by R^{T}'s preferably represents the above-described *-L_{N}-R^{pA}. m represents an integer of 0 to 4 and preferably represents an integer of 1 to 4.

The above-described specific resin 2 may include a repeating unit other than the above-described repeating units within a range that does not impair the effects of the present invention. The additional repeating unit is not particularly limited, and examples thereof include the repeating units represented by the formula (2) that can be included in the above-described specific resin 1 (preferably repeating units represented by the formula (3)).

### Other Aspect of Specific Resin

The specific resin preferably includes one or more functional groups (specific functional groups) selected from the group consisting of a hydroxy group (an alcoholic hydroxy group and a phenolic hydroxy group), a carboxyl group, an amino group, an amide group, a thiol group, and an acetoxy group, in the point that the effect of the present invention is more excellent as described above, and more preferably includes one or more functional groups selected from the group consisting of a phenolic hydroxy group and a carboxyl group.

Here, the phenolic hydroxy group means a hydroxy group substituted for a ring member atom of an aromatic ring.

The aromatic ring is not limited to a benzene ring and may be an aromatic hydrocarbon ring or an aromatic heterocyclic ring. The aromatic ring may be monocyclic or polycyclic.

The alcoholic hydroxy group is distinguished from a phenolic hydroxy group and, in the present specification, means a hydroxy group substituting for an aliphatic hydrocarbon group.

The amino group is preferably a group represented by —N(R^{P})₂, and the amide group is preferably a group represented by —CO—N(R^{q})₂ or a group represented by —CO—N(R^{q})—. R^{P} and R^{q} each independently represents preferably a hydrogen atom or a monovalent organic group (preferably, an alkyl group having 1 to 6 carbon atoms) and more preferably a hydrogen atom. The case where the specific resin includes a group represented by —CO—N(R^{q})— as the specific functional group corresponds to, for example, the case where R⁰ and R^{1A} in the repeating unit represented by the above-described formula (1) are linked to each other to form a ring and the ring has therein a structural site represented by —CO—N(R^{q})— (preferably, a structural site represented by —CO—N(R^{q})—CO—).

The specific resin preferably includes a repeating unit including a specific functional group, in the point that the effect of the present invention is more excellent.

In the specific resin, the content of the repeating unit including the specific functional group is preferably 5 to 100 mol %, more preferably 10 to 100 mol %, and further preferably 20 to 100 mol % relative to the total repeating units of the specific resin.

In the specific resin, the repeating unit including the specific functional group may be composed of one type or two or more types. When the repeating unit including the specific functional group is composed of two or more types, the total content is preferably in the above numerical range.

In the specific resin, the repeating unit including the specific functional group may be any repeating unit as long as it includes a specific functional group. For example, when the repeating unit represented by the above-described formula (1) includes a specific functional group, it corresponds to the repeating unit including a specific functional group. In addition, the repeating unit represented by the above-described formula (3) includes a specific functional group and therefore corresponds to the repeating unit including a specific functional group.

The specific resin can be synthesized according to a usual method (e.g., radical polymerization).

The weight average molecular weight of the specific resin is preferably 1,000 to 200,000, more preferably 2,500 to 150,000, and further preferably 25,00 to 80,000, as a polystyrene equivalent value by a GPC method, When the weight average molecular weight is within the above numerical value range, deterioration of the heat resistance and dry etching resistance can be further suppressed. In addition, deterioration of developability and deteriorating of the film-forming property by an increase in the viscosity also can be further suppressed.

The dispersity (molecular weight distribution) of the specific resin is usually 1.0 to 5.0, preferably 1.0 to 3.0, more preferably 1.2 to 3.0, and further preferably 1.2 to 2.0. The smaller the dispersity, the more excellent the resolution and resist shape.

In the resist composition, the content of the specific resin is preferably 50 mass % or more, more preferably 60 mass % or more, further preferably 65 mass % or more, and particularly preferably 70 mass % or more relative to the total solid content of the composition. The upper limit is preferably 99 mass % or less and more preferably 95 mass % or less.

One type of the specific resin may be used, or a combination of two or more types of the specific resin may be used. When two or more types are used, the total content thereof is preferably within the range of the above preferable content.

Examples of the specific resin are shown below, but the specific resin of the present invention is not limited thereto.

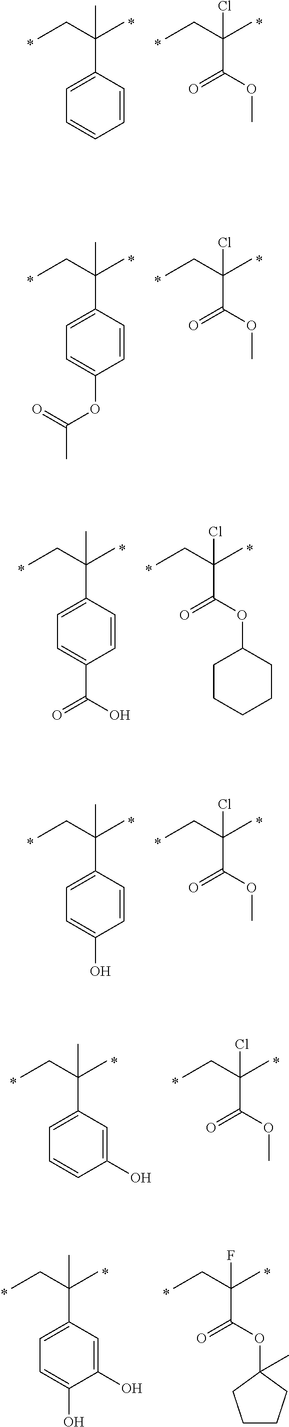

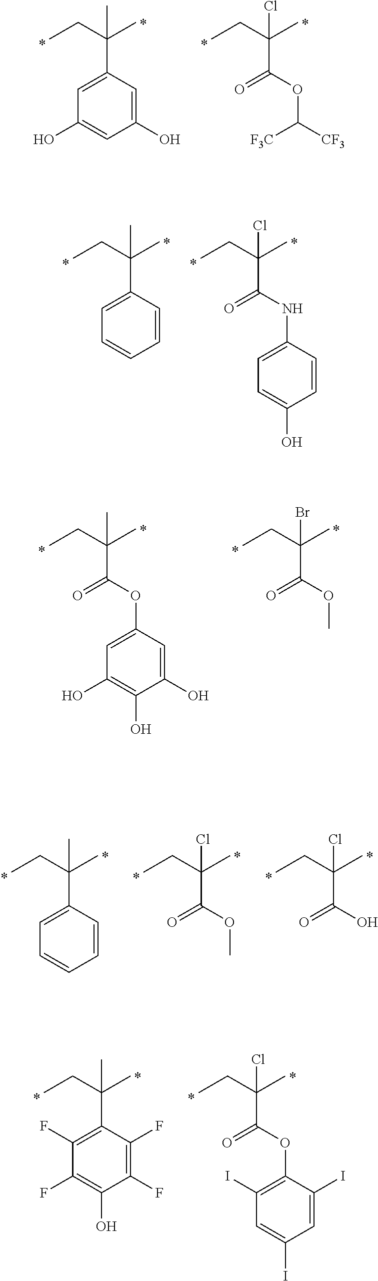

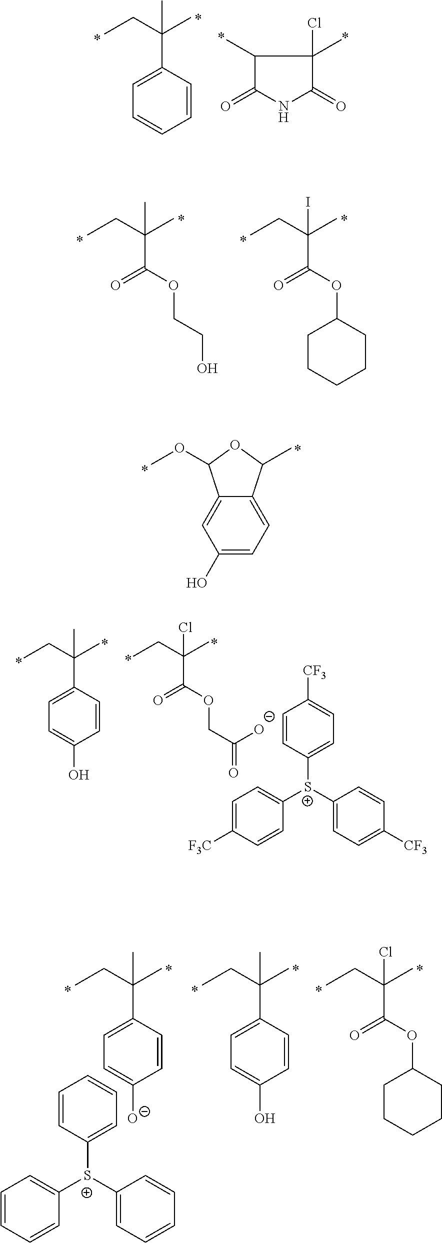

### Specific Metal Compound

The resist composition includes one or more metal compounds (specific metal compound) selected from the group consisting of a metal complex, an organic metal salt, and an organic metal compound.

Examples of the metal atom included in the metal compound include a lithium atom, a sodium atom, a magnesium atom, an aluminum atom, a potassium atom, a calcium atom, a scandium atom, a titanium atom, a vanadium atom, a chromium atom, a manganese atom, an iron atom, a cobalt atom, a nickel atom, a copper atom, a zinc atom, a gallium atom, a rubidium atom, a strontium atom, an yttrium atom, a zirconium atom, a ruthenium atom, a rhodium atom, a palladium atom, a silver atom, a cadmium atom, an indium atom, a tin atom, an antimony atom, a cesium atom, a barium atom, a hafnium atom, a tungsten atom, a rhenium atom, an osmium atom, a iridium atom, a platinum atom, a gold atom, a mercury atom, a thallium atom, a lead atom, a bismuth atom, a lanthanum atom, a cerium atom, a prascodymium atom, a neodymium atom, a samarium atom, a europium atom, a gadolinium atom, a terbium atom, a dysprosium atom, a holmium atom, an erbium atom, a thulium atom, an ytterbium atom, and a lutetium atom.

In the point that the sensitivity is more excellent, the metal compound preferably includes, in particular, one or more atoms selected from the group consisting of an iron atom, a titanium atom, a cobalt atom, a nickel atom, a zinc atom, a silver atom, an indium atom, a tin atom, and a hafnium atom and more preferably one or more atoms selected from the group consisting of an iron atom, a tin atom, and a hafnium atom.

Examples of the metal complex include a metal complex including a center metal atom (preferably, a transition metal atom or a typical metal atom such as zinc) and a ligand forming a coordinate bond with the center metal atom (e.g., a neutral or anionic monodentate ligand or neutral or anionic polydentate ligand (preferably, a bidentate ligand)). The metal complex is, in particular, preferably a metal complex including a center metal atom and an organic ligand that forms a coordinate bond with the center metal atom. Here, the term “organic ligand” refers to a ligand including at least one carbon atom.

It is also preferable that at least one of the ligands in the metal complex is an organic ligand.

Examples of the center metal atom include the above-described metal atoms.

Examples of the bond between a center metal atom and a ligand include a metal-nitrogen bond, a metal-carbon bond, a metal-oxygen bond, a metal-phosphorus bond, a metal-sulfur bond, and a metal-halogen bond.

Examples of the ligand included in the metal complex include a halogen atom, an alkyl group, a cycloalkyl group, an acyl group (e.g., an acetylacetonato group), a carbonyl group, an isocyanide group, an alkene group (e.g., a butadiene group and a cyclooctadiene group), an alkyne group, an aryl group (e.g., benzene and naphthalene), an alkylidene group, an alkylidyne group, a cyclopentadienyl group, an indenyl group, a cycloheptatrienium group, a cyclobutadiene group, a nitrogen molecule, a nitro group, a phosphene group, a phosphine group, a thiol group, a hydroxy group, an amine group, an ether group, an alkoxide group, an amide group, and a silyl group.

Examples of the organic metal salt include a salt consisting of a metal ion and an organic counter ion (a salt composed of a metal cation and an organic anion and a salt composed of a metal anion and an organic cation), and, in particular, a salt composed of a metal cation and an organic anions is preferable. Here, the term “organic counter ion” refers to a counter ion including at least one carbon atom.

Examples of the metal ion include metal ions of the above-described metal atom species.

The organic counter ion is not particularly limited, and examples thereof include an organic cation including a quaternary nitrogen atom (e.g., a pyridinium ion), a sulfonate anion (such as an aliphatic sulfonate anion and an aromatic sulfonate anion (e.g., a perfluoromethylsulfonate anion)), and a carboxylate anion (such as an aliphatic carboxylate anion and an aromatic carboxylate anion (e.g., a 2-pyridinecarboxylate anion)).

Examples of the organic metal compound include a compound including at least one metal-carbon bond (in particular, a metal-carbon covalent bond). One aspect of the organic metal compound is an organic tin compound. Examples of the organic tin compound include groups represented by the following formula (1S) or (2S).

Sn(R^{S1})ₚ(R^{S2})q Formula (1S):

In the formula (1S), R^{S1} represents an alkyl group, an alkenyl group, an alkynyl group, or an aryl group.

The alkyl group represented by R^{S1} may be linear, branched, or cyclic. The number of carbon atoms of the alkyl group is preferably 1 to 20, more preferably 1 to 8, and further preferably 1 to 6. Examples of the alkyl group include linear or branched alkyl groups, such as a methyl group, an ethyl group, an n-propyl group, an i-propyl group, an n-butyl group, a t-butyl group, and an n-hexyl group; monocyclic cycloalkyl groups, such as a cyclopentyl group and a cyclohexyl group; and polycyclic cycloalkyl groups, such as a norbornyl group, a tetracyclodecanyl group, a tetracyclododecanyl group, and an adamantyl group.

The alkyl group may further have a substituent.

The alkenyl group represented by R^{S1} may be linear, branched, or cyclic. The number of carbon atoms of the alkenyl group is preferably 2 to 20, more preferably 2 to 10, and further preferably 2 to 6. The alkenyl group may further have a substituent.

The alkynyl group represented by R^{S1} may be linear, branched, or cyclic. The number of carbon atoms of the alkynyl group is preferably 2 to 20, more preferably 2 to 10, and further preferably 2 to 6. The alkynyl group may further have a substituent.

The aryl group represented by RSI may be monocyclic or polycyclic (e.g., 2 to 6 rings).

The number of ring member atoms of the aryl group is preferably 6 to 15 and more preferably 6 to 10.

The aryl group is preferably a phenyl group, a naphthyl group, or an anthranil group and more preferably a phenyl group. The aryl group may further have a substituent.

R^{S2} represents an alkylcarbonyloxy group or a mono- or dialkylamino group. Here, the mono- or dialkylamino group means a group in which one or two of the hydrogen atoms of an amino group is substituted with an alkyl group.

Examples of the alkyl group portion in the alkylcarbonyloxy group and the alkyl group portion in the mono- or dialkylamino group include the same aspect as that in the alkyl group represented by R^{S1}.

Examples of the alkylcarbonyloxy group include an acetoxy group.

Examples of the mono- or dialkylamino group include a diethylamino group.

In the formula (1S), p represents an integer of 1 to 4, and q represents an integer of 0 to 3, wherein p+q=4.

In the formula (1S), in particular, p preferably represents an integer of 1 or 2.

R^{S3}—Sn(═O)—OH Formula (2S):

In the formula (2S), R^{S3} represents an alkyl group, an alkenyl group, an alkynyl group, or an aryl group.

Examples of the alkyl group, the alkenyl group, the alkynyl group, and the aryl group represented by R^{S3} include the same alkyl group, alkenyl group, alkynyl group, and aryl group as those represented by R^{S1} in the formula (1S).

As the metal complex, organic metal salt, and organic metal compound, in addition to those mentioned above, those described, for example, in Organotransition Metal Chemistry, Volumes 1 and 2 (written by John F. Hartwig, Tokyo Kagaku Dozin, 2014), Shriver and Atkins' Inorganic Chemistry, Volumes 1 and 2 (written by M. Weller, T. Overton, J. Rourke, and F. Armstrong, Tokyo Kagaku Dojin, 2016), or Dictionary of Inorganic Compounds & Complexes (written by Masayoshi Nakahara, Kodansha Scientific, 1997) also can be used.

The content of the metal compound in the resist composition is preferably 0.1 mass % or more, more preferably 1 mass % or more, and further preferably 3 mass % or more relative to the total solid content of the composition. The upper limit is preferably 50 mass % or less, more preferably 40 mass % or less, and further preferably 35 mass % or less.

One type of the metal compound may be used, or two or more types of the metal compound may be used. When two or more types are used, the total content thereof is preferably within the range of the above preferable content.

The content of the metal compound in the resist composition is preferably 1 to 40 mass %, more preferably 1 to 35 mass %, and further preferably 1 to 30 mass % relative to the content of the specific resin.

Examples of the metal compound are shown below, but the metal compound of the present invention is not limited thereto.

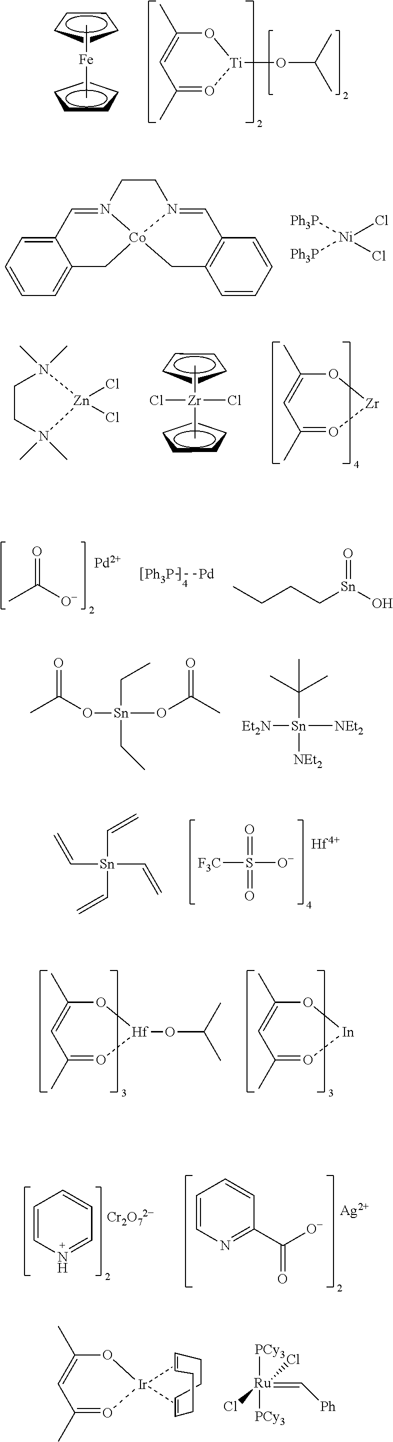

### Solvent

The resist composition includes a solvent.

The solvent is not particularly limited, but preferably includes at least one of (M1) propylene glycol monoalkyl ether carboxylate or (M2) at least one selected from the group consisting of a propylene glycol monoalkyl ether, a lactate, an acetate, an alkoxypropionate, a linear ketone, a cyclic ketone, lactone, and alkylene carbonate. This solvent may further include a component other than the components (M1) and (M2).

When such a solvent and a specific resin are used in combination, the coating property of the resist composition is improved, and also a pattern with a small number of development defects is easily formed. The reason for this is presumed that these solvents have an excellent balance of specific resin solubility, boiling point, and viscosity and therefore can suppress the unevenness in the film thickness of a resist film, which is the composition film of the resist composition, and the occurrence of educt during spin coating.

The component (M1) is preferably at least one selected from the group consisting of propylene glycol monomethylether acetate (PGMEA:), propylene glycol monomethylether propionate, and propylene glycol monoethylether acetate, and more preferably propylene glycol monomethylether acetate (PGMEA).

The component (M2) is preferably the followings.

The propylene glycol monoalkylether is preferably propylene glycol monomethylether (PGME) or propylene glycol monocthylether.

The lactate is preferably ethyl lactate, butyl lactate, or propyl lactate.

The acetate is preferably methyl acetate, ethyl acetate, butyl acetate, isobutyl acetate, propyl acetate, isoamyl acetate, or 3-methoxybutyl acetate.

Butyl butyrate is also preferable.

The alkoxy propionate is preferably methyl 3-methoxypropionate (MMP) or ethyl 3-ethoxypropionate (EEP).

The linear ketone is preferably 1-octanone, 2-octanone, 1-nonanone, 2-nonanone, acetone, 2-heptanone, 4-heptanone, 1-hexanone, 2-hexanone, diisobutyl ketone, phenylacetone, methyl ethyl ketone, methyl isobutyl ketone, acetylacetone, acetonylacetone, ionone, diacetonyl alcohol, acetyl carbinol, acetophenone, methyl naphthyl ketone, or methyl amyl ketone.

The cyclic ketone is preferably methylcyclohexanone, isophorone, or cyclohexanone.

The lactone is preferably γ-butyrolactone.

The alkylene carbonate is preferably propylene carbonate.

The component (M2) is more preferably propylene glycol monomethylether (PGME), ethyl lactate, ethyl 3-ethoxypropionate, methyl amyl ketone, cyclohexanone, butyl acetate, pentyl acetate, γ-butyrolactone, or propylene carbonate.

The solvent preferably includes an ester solvent having 7 or more carbon atoms (preferably 7 to 14, more preferably 7 to 12, and further preferably 7 to 10) and having 2 or less hetero atoms, in addition to the above-described components.

The ester solvent having 7 or more carbon atoms and 2 or less hetero atoms is preferably amyl acetate, 2-methylbutyl acetate, 1-methylbutyl acetate, hexyl acetate, pentyl propionate, hexyl propionate, butyl propionate, isobutyl isobutyrate, heptyl propionate, or butyl butanoate and more preferably isoamyl acetate.

The component (M2) preferably has a flash point (hereinafter, also referred to as fp) of 37° C. or more. Such a component (M2) is preferably propylene glycol monomethylether (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), methyl 2-hydroxyisobutyrate (fp: 45° C.), γ-butyrolactone (fp: 101° C.), or propylene carbonate (fp: 132° C.). Among them, propylene glycol monocthylether, ethyl lactate, pentyl acetate, and cyclohexanone are more preferable, and propylene glycol monoethylether and ethyl lactate are further preferable.

Here, the term “flash point” means the values listed in reagent catalogs of Tokyo Chemical Industry Co., Ltd. or Sigma-Aldrich Co. LLC.

The solvent preferably includes the component (M1). The solvent more preferably consists substantially of the component (M1) only or a mixture solvent of the component (M1) and another component. In the latter case, the solvent further preferably includes both the component (M1) and the component (M2).

The mass ratio (M1/M2) of the component (M1) and the component (M2) is preferably within a range of “100/0” to “15/85”, more preferably within a range of “100/0” to “40/60”, and further preferably within a range of “100/0” to “60/40”. That is, it is preferable that the solvent consists of the component (M1) only or includes both the component (M1) and the component (M2) at a mass ratio shown below. Namely, in the latter case, the mass ratio of the component (M1) to the component (M2) is preferably 15/85 or more, more preferably 40/60 or more, and further preferably 60/40 or more. By adopting such a configuration, the number of development defects can be further decreased.

When the solvent includes both the component (M1) and the component (M2), the mass ratio of the component (M1) to the component (M2) is set to, for example, 99/1 or less.

When the solvent further includes a component other than the components (M1) and (M2), the content of the component other than the components (M1) and (M2) is preferably 5 to 30 mass % relative to the total amount of the solvent.

The content of the solvent in the resist composition is determined such that the concentration of solid contents is preferably 0.5 to 30 mass % and more preferably 1 to 20 mass %, in the point that the coating property is more excellent.

### Other Component

The resist composition may include another component other than the specific resin, specific metal compound, and solvent.

The additional component is not particularly limited, but examples thereof include a photodegradable onium salt compound and a surfactant.

### Photodegradable Onium Salt Compound

The resist composition preferably includes a compound with an onium salt structure that generates an acid by irradiation with an active light ray or radioactive ray (photodegradable onium salt compound).

When the resist composition includes a photodegradable onium salt compound, in the unexposed portion, the specific resin easily aggregates with the photodegradable onium salt compound through the relatively high polar functional group or specific functional group that can be included in the specific resin. On the other hand, the aggregation structure can be released by cleavage of the photodegradable onium salt compound by receiving exposure. That is, the dissolution contrast between the unexposed portion and the exposed portion in the resist film is further enhanced by the above action, and the effect of the present invention easily becomes more excellent.

The photodegradable onium salt compound is preferably a compound that has at least one salt structure site constituted of an anionic site and a cationic site and generates an acid (preferably an organic acid) through decomposition by exposure.

In the point that the salt structure site of the photodegradable onium salt compound is easily decomposed by exposure and is more excellent in the organic acid-generating property, in particular, it is preferable to be composed of an organic cationic site and an organic anionic site with extremely low nucleophilicity.

The salt structure site may be a part or the whole of the photodegradable onium salt compound. The case where the salt structure site is a part of the photodegradable onium salt compound corresponds to, for example, a structure in which two or more salt structure sites are linked to each other as in the photodegradable onium salt PG2 described later.

The number of the salt structure sites in the photodegradable onium salt is not particularly limited, but is preferably 1 to 10, more preferably 1 to 6, and further preferably 1 to 3.

Examples of the organic acid that is generated from the photodegradable onium salt compound by the above-described action of exposure include sulfonic acid (such as aliphatic sulfonic acid, aromatic sulfonic acid, and camphor sulfonic acid), carboxylic acid (such as aliphatic carboxylic acid, aromatic carboxylic acid, and aralkyl carboxylic acid), carbonylsulfonylimide acid, bis(alkylsulfonyl)imide acid, and tris(alkylsulfonyl)methide acid.

The organic acid that is generated from the photodegradable onium salt compound by the action of exposure may be a polyacid having two or more acid groups. For example, when the photodegradable onium salt compound is a photodegradable onium salt compound PG2 described later, the organic acid that is generated by decomposition of the photodegradable onium salt compound by exposure is a polyacid having two or more acid groups.

In the photodegradable onium salt compound, the cationic site constituting the salt structure site is preferably an organic cationic site, in particular, preferably an organic cation (cation (ZaI)) represented by the above-described formula (ZaI) or an organic cation (cation (ZaII)) represented by the formula (ZaII).

### Photodegradable Onium Salt Compound PG1

One example of a preferable aspect of the photodegradable onium salt compound is an onium salt compound represented by “M⁺ X⁻”, and examples thereof include a compound (hereinafter, also referred to as “photodegradable onium salt compound PG1”) that generates an organic acid by exposure.

In the compound represented by “M⁺ X⁻”, M⁺ represents an organic cation, and X⁻ represents an organic anion.

The photodegradable onium salt compound PG1 will now be described.

The organic cation represented by M⁺ in the photodegradable onium salt compound PG1 is preferably an organic cation (cation (ZaI)) represented by the above-described formula (ZaI) or an organic cation (cation (ZaII)) represented by the formula (ZaII).

The organic anion represented by X⁻ in the photodegradable onium salt compound PG1 is preferably a non-nucleophilic anion (an anion with extremely low ability to cause a nucleophilic reaction).

Examples of the non-nucleophilic anion include a sulfonate anion (such as an aliphatic sulfonate anion, an aromatic sulfonate anion, and a camphor sulfonate anion), a carboxylate anion (such as an aliphatic carboxylate anion, an aromatic carboxylate anion, and an aralkyl carboxylate anion), a sulfonylimide anion, a bis(alkylsulfonyl)imide anion, and a tris(alkylsulfonyl)methide anion.

The aliphatic site in the aliphatic sulfonate anion and the aliphatic carboxylate anion may be an alkyl group or a cycloalkyl group, and are preferably a linear or branched alkyl group having 1 to 30 carbon atoms and a cycloalkyl group having 3 to 30 carbon atoms.

The alkyl group may be, for example, a fluoroalkyl group (which may or may not have a substituent other than the fluorine atom, and may be a perfluoroalkyl group).

The aryl group in the aromatic sulfonate anion and aromatic carboxylate anion is preferably an aryl group having 6 to 14 carbon atoms, and examples thereof include a phenyl group, a tolyl group, and a naphthyl group.

The above-mentioned alkyl group, cycloalkyl group, and aryl group may have a substituent. The substituent is not particularly limited, but examples thereof include a nitro group, a halogen atom such as a fluorine atom and a chlorine atom, a carboxy group, a hydroxy group, an amino group, a cyano group, an alkoxy group (preferably having 1 to 15 carbon atoms), an alkyl group (preferably having 1 to 10 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), and an aryloxysulfonyl group (preferably having 6 to 20 carbon atoms).

The aralkyl group in the aralkyl carboxylate anion is preferably an aralkyl group having 7 to 14 carbon atoms, and examples thereof include a benzyl group, a phenethyl group, a naphthylmethyl group, a naphthylethyl group, and a naphthylbutyl group.

Examples of the sulfonylimide anion include a saccharin anion.

The alkyl group in the bis(alkylsulfonyl)imide anion and tris(alkylsulfonyl)methide anion is preferably an alkyl group having 1 to 5 carbon atoms. Examples of the substituent of these alkyl groups include a halogen atom, an alkyl group substituted with a halogen atom, an alkoxy group, an alkylthio group, an alkyloxysulfonyl group, an aryloxysulfonyl group, and a cycloalkylaryloxysulfonyl group, and a fluorine atom and an alkyl group substituted with a fluorine atom are preferable.

The alkyl groups in the bis(alkylsulfonyl)imide anion may be bound to each other to form a ring structure. Consequently, the acid strength is increased.

The non-nucleophilic anion is preferably an aliphatic sulfonate anion in which at least α-position of sulfonic acid is substituted with a fluorine atom, an aromatic sulfonate anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom.

The organic anion represented by X-in the photodegradable onium salt compound PG1 is preferably, for example, an organic anion represented by the following formula (DA).

A₃₁^{⊖}-Lₐ₁-Rₐ₁ (DA)

In the formula (DA), A³¹⁻represents an anionic group. Rₐ₁ represents a hydrogen atom or a monovalent organic group. Lai represents a single bond or a divalent linker group.

A³¹⁻represents an anionic group. The anionic group represented by A³¹⁻ is not particularly limited, but is preferably a group selected from the group consisting of the groups represented by the above-described formulae (B-1) to (B-14).

The monovalent organic group of Rₐ₁ is not particularly limited, but generally has 1 to 30 carbon atoms and preferably 1 to 20 carbon atoms.

Rₐ₁ is preferably an alkyl group, a cycloalkyl group, or an aryl group.

The alkyl group may be linear or branched, and is preferably an alkyl group having 1 to 20 carbon atoms, more preferably an alkyl group having 1 to 15 carbon atoms, and further preferably an alkyl group having 1 to 10 carbon atoms.

The cycloalkyl group may be monocyclic or polycyclic, and is preferably a cycloalkyl group having 3 to 20 carbon atoms, more preferably a cycloalkyl group having 3 to 15 carbon atoms, and further preferably a cycloalkyl group having 3 to 10 carbon atoms.

The aryl group may be monocyclic or polycyclic, and is preferably an aryl group having 6 to 20 carbon atoms, more preferably an aryl group having 6 to 15 carbon atoms, and further preferably an aryl group having 6 to 10 carbon atoms.

The cycloalkyl group may include a hetero atom as a ring member atom.

The hetero atom is not particularly limited, but examples thereof include a nitrogen atom and an oxygen atom.

The cycloalkyl group may include a carbonyl bond (>C═O) as a ring member atom.

The alkyl group, cycloalkyl group, and aryl group may further have a substituent.

The divalent linker group as Lai is not particularly limited, but is an alkylene group, a cycloalkylene group, an aromatic group, —O—, —CO—, —COO—, or a group consisting of a combination of two or more thereof.

The alkylene group may be linear or branched, and the number of carbon atoms is preferably 1 to 20 and more preferably 1 to 10.

The cycloalkylene group may be monocyclic or polycyclic, and the number of carbon atoms is preferably 3 to 20 and more preferably 3 to 10.

The aromatic group is a divalent aromatic group, and an aromatic group having 6 to 20 carbon atoms is preferable, and an aromatic group having 6 to 15 carbon atoms is more preferable.

The aromatic ring constituting the aromatic group is not particularly limited, but examples thereof include an aromatic ring having 6 to 20 carbon atoms, specifically, a benzene ring, a naphthalene ring, an anthracene ring, and a thiophene ring. The aromatic ring constituting the aromatic group is preferably a benzene ring or a naphthalene ring and more preferably a benzene ring.

The alkylene group, cycloalkylene group, and aromatic group may further have a substituent, and the substituent is preferably a halogen atom.

A³¹⁻ and Rₐ₁ may be bound to each other to form a ring.

As the photodegradable onium salt compound PG1, for example, the photoacid generators disclosed in paragraphs [0135] to [0171] of WO 2018/193954A, paragraphs [0077] to [0116] of WO 2020/066824A, and paragraphs [0018] to [0075] and [0334] to [0335] of WO 2017/154345A can also be preferably used.

As the photodegradable onium salt compound, a compound having a betaine structure in which an organic anion represented by the above-described X⁻ and an organic cation represented by the above-described M⁺ are bound through a covalent bond can also be used.

The molecular weight of the photodegradable onium salt compound PG1 is preferably 3000 or less, more preferably 2000 or less, and further preferably 1000 or less. Photodegradable onium salt compound PG2

Other examples of a preferable aspect of the photodegradable onium salt compound include the following compound (I) and compound (II) (hereinafter, “the compound (I) and the compound (II)” are also referred to as “photodegradable onium salt compound PG2”). The photodegradable onium salt compound PG2 is a compound that has two or more salt structure sites described above and generates a polyvalent organic acid by exposure.

The photodegradable onium salt compound PG2 will now be described.

### Compound (I)

The compound (I) is a compound that has one or more structural sites Xs shown below and one or more structural sites Ys shown below and generates an acid including a first acidic site derived from the structural site X and a second acidic site derived from the structural site Y by irradiation with an active light ray or radioactive ray.

Structural site X: a structural site consisting of an anionic site A₁⁻ and a cationic site M₁⁺ and forming a first acid site represented by HA₁ by irradiation with an active light ray or radioactive ray.

Structural site Y: a structural site consisting of an anionic siteA₂⁻ and a cationic siteM₂⁺ and forming a second acidic site represented by HA₂ by irradiation with an active light ray or radioactive ray.

However, the compound (I) satisfies the following requirement I.

Requirement I: a compound PI in which the cationic site M₁⁺ in the structural site X and the cationic site M₂⁺ in the structural site Y in the compound (I) are replaced by H⁺ has an acid dissociation constant a1 derived from the acidic site represented by HA₁ in which the cationic site M₁⁺ in the structural site X is replaced by H⁺ and an acid dissociation constant a2 derived from the acidic site represented by HA₂ in which the cationic site M₂⁺ in the structural site Y is replaced by H⁺, wherein the acid dissociation constant a2 is larger than the acid dissociation constant a1.

The compound PI corresponds to an acid that occurs when the compound (I) is irradiated with an active light ray or radioactive ray.

When the compound (I) has two or more structural sites Xs, the structural sites Xs may be the same or different. The two or more A₁⁻'s may be the same or different, and the two or more M₁⁺'s may be the same or different.

In the compound (I), A₁⁻ and A₂⁻ may be the same or different, and M₁⁺ and M₂⁺ may be the same or different, but A₁⁻ and A₂⁻ are preferably different.

The anionic site A₁⁻ and the anionic site A₂⁻ are structural sites including a negatively charged atom or atomic group, and examples thereof include a structural site selected from the group consisting of formulae (AA-1) to (AA-3) and formulae (BB-1) to (BB-6) shown below. In the formulae (AA-1) to (AA-3) and formulae (BB-1) to (BB-6) below, * represents a binding site, and R^{A} represents a monovalent organic group. Examples of the monovalent organic group represented by R^{A} include a cyano group, a trifluoromethyl group, and a methanesulfonyl group.

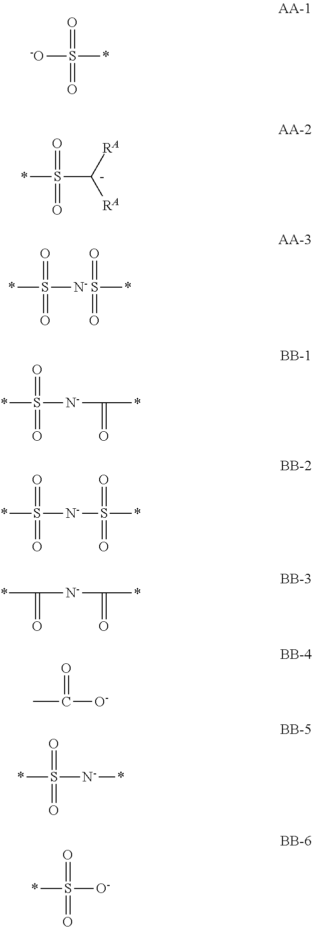

The cationic site M₁⁺ and the cationic site M₂⁺ are structural sites including a positively charged atom or atomic group, and examples thereof include a singly charged organic cation. The organic cation is not particularly limited, but is preferably an organic cation (cation (ZaI)) represented by the above-described formula (ZaI) or an organic cation (cation (ZaII)) represented by the formula (ZaII).

### Compound (II)′

The compound (II) is a compound having two or more structural sites Xs described above and one or more structural sites Zs described below, wherein the compound generates an acid including two or more first acidic sites derived from the structural sites Xs and the structural site Z by irradiation with an active light ray or radioactive ray.

Structural site Z: a nonionic site that can neutralize an acid.

The compound (II) can generate a compound PII (acid) having an acidic site represented by HA₁ in which the cationic site M₁⁺ in the structural site X is replaced by H⁺ by irradiation with an active light ray or radioactive ray. That is, the compound PII represents a compound having an acidic site represented by HA₁ and a structural site Z that is a nonionic site being capable of neutralizing an acid.

In the compound (II), the definition of the structural site X and the definitions of A₁⁻ and M₁⁺ are synonymous with the definition of the structural site X and definitions of A₁⁻ and M₁⁺ in the above-described compound (I), and a preferable aspect is also the same.

The two or more structural sites Xs may be the same or different. The two or more A₁⁻'s may be the same or different, and the two or more M₁⁺'s may be the same or different.

The nonionic site that can neutralize the acid in the structural site Z is not particularly limited, and is preferably, for example, a site including a functional group having a group or electron that can electrostatically interact with a proton.

Examples of the functional group having a group or electron that can electrostatically interact with a proton include a functional group having a macrocyclic structure, such as a cyclic polyether, and a functional group having a nitrogen atom with an unshared electron pair that does not contribute to π conjugation. The nitrogen atom with an unshared electron pair that does not contribute to π conjugation is, for example, a nitrogen atom having a partial structure shown by the following formulae.

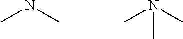

[symbol]

unshared electron pair

Examples of the partial structure of the functional group having a group or electron that can electrostatically interact with a proton include a crown ether structure, an azacrown ether structure, primary to tertiary amine structures, a pyridine structure, an imidazole structure, and a pyrazine structure, and, in particular, primary to tertiary amine structures are preferable.

The molecular weight of the photodegradable onium salt compound PG2 is preferably 100 to 10000, more preferably 100 to 2500, and further preferably 100 to 1500.

As the photodegradable onium salt compound PG2, compounds exemplified in paragraphs [0023] to [0095] of WO 2020/158313A can be cited.

When the resist composition includes a photodegradable onium salt compound, the content thereof is not particularly limited, but is preferably 0.5 mass % or more, more preferably 1 mass % or more, and further preferably 5 mass % or more relative to the total solid content of the composition. The content is preferably 40 mass % or less and more preferably 30 mass % or less.

One type of the photodegradable onium salt compound may be used, or two or more types of the photodegradable onium salt compound may be used. When two or more types are used, the total content thereof is preferably within the range of the above preferable content.

Examples of the site other than a cation that the photodegradable onium salt compound PG2 can have are shown below.

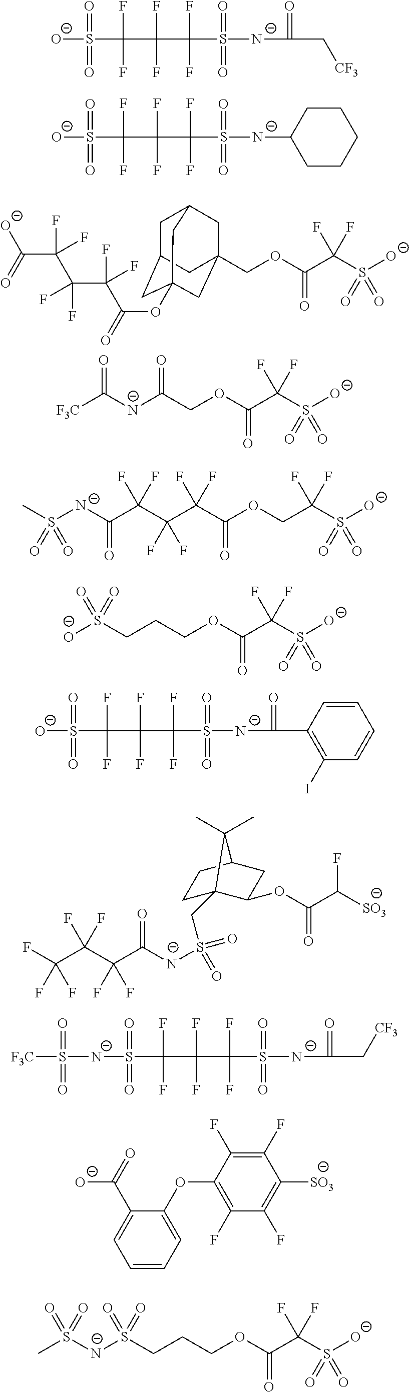

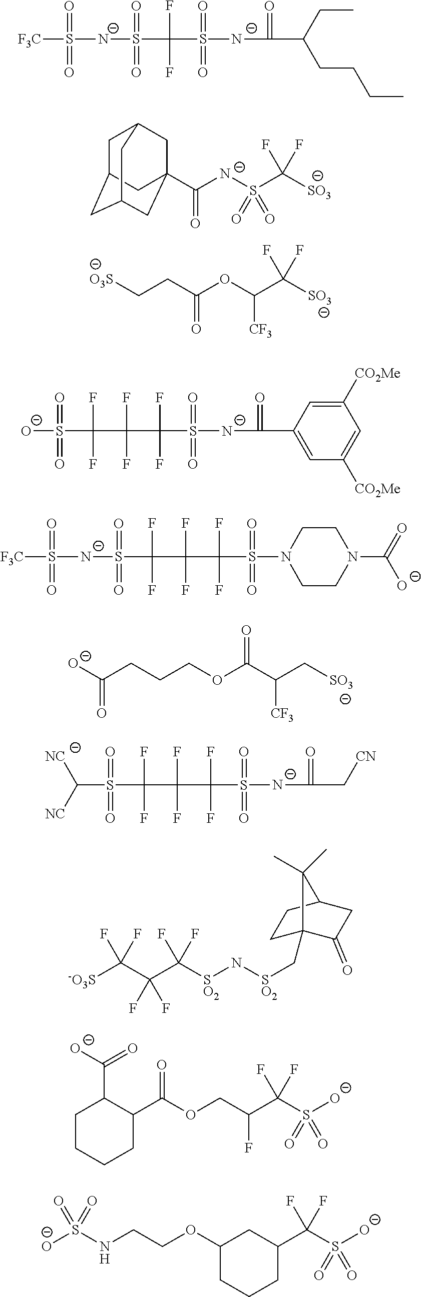

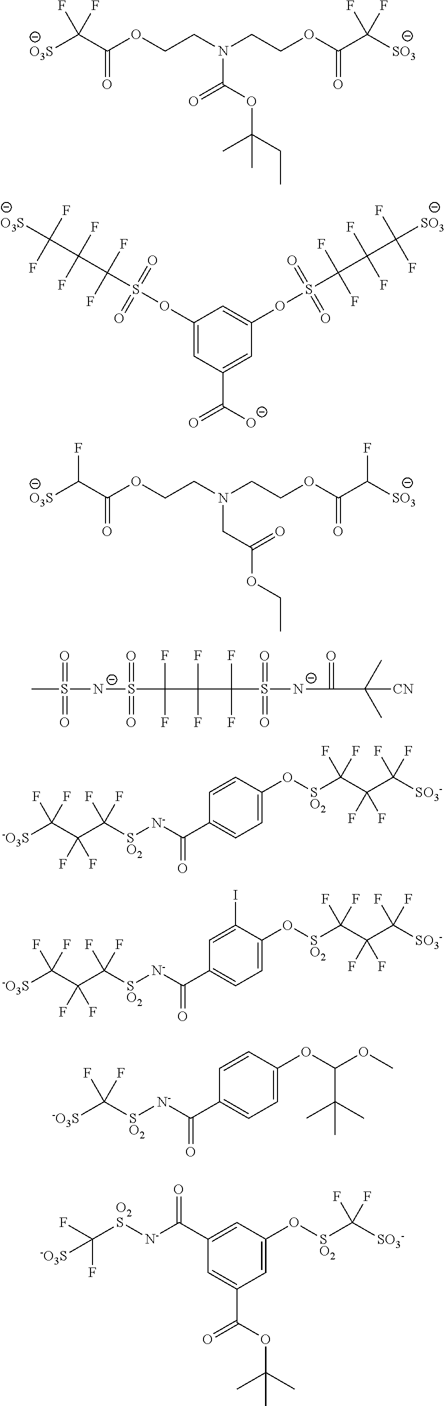

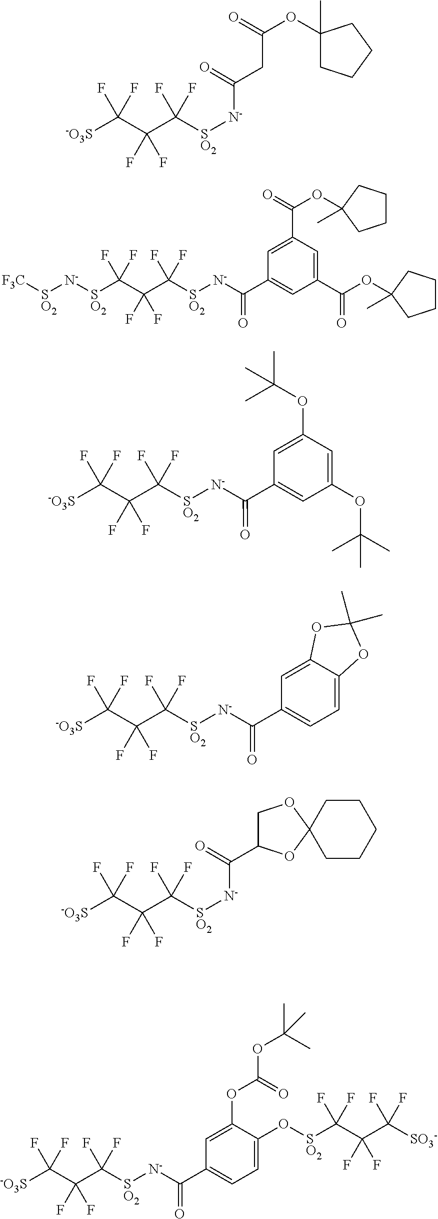

Examples of the photodegradable onium salt compound PG2 are shown below, but are not limited thereto.

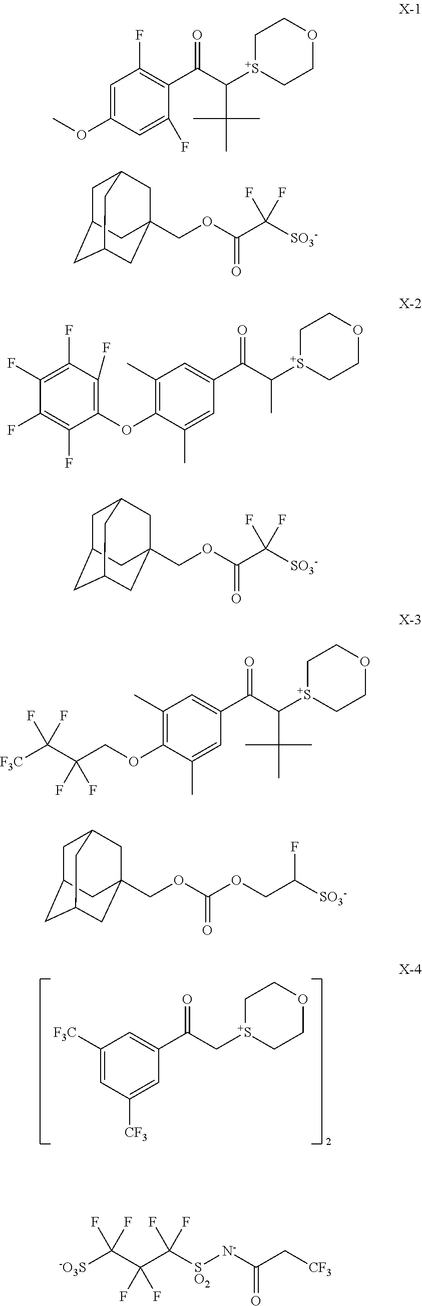

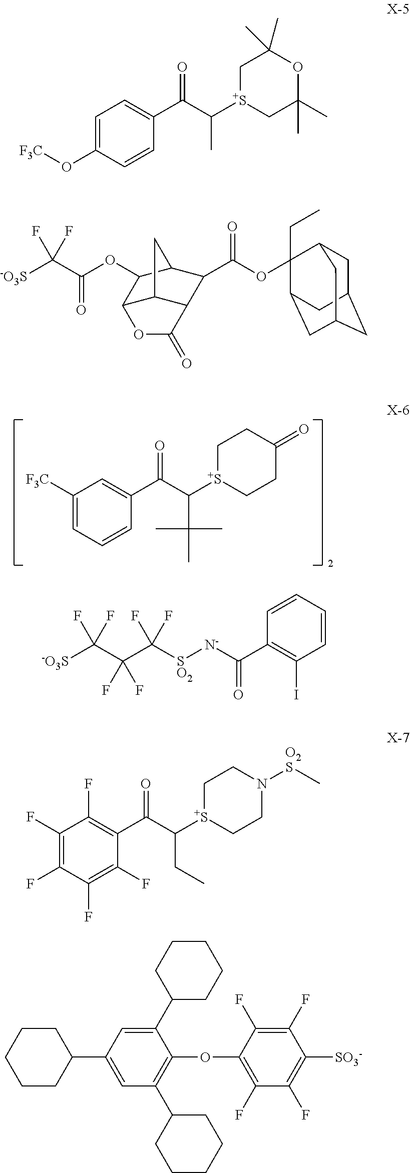

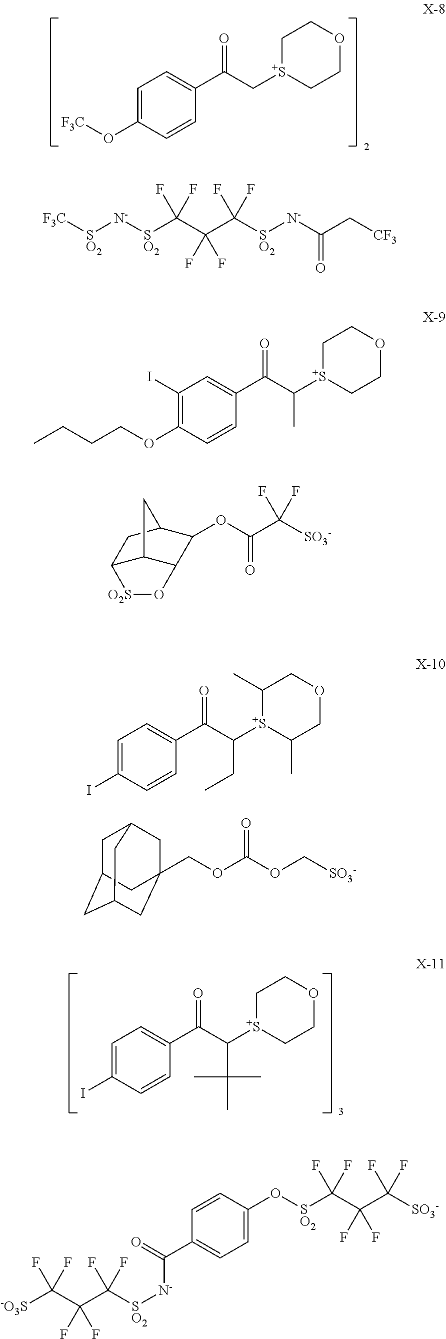

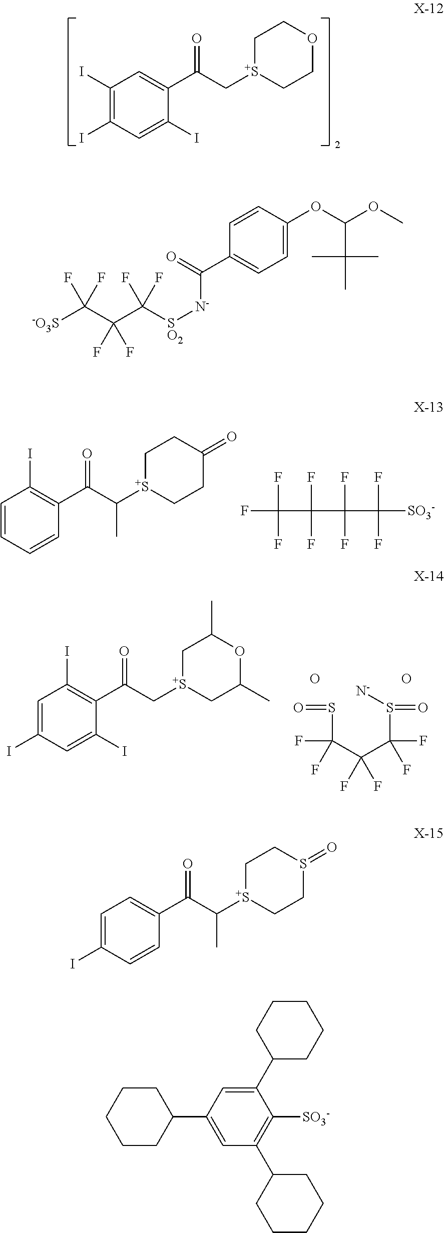

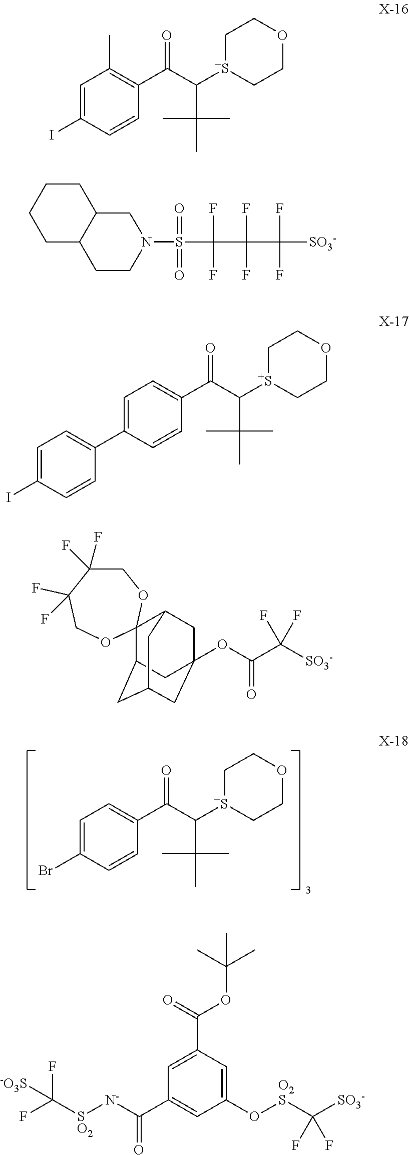

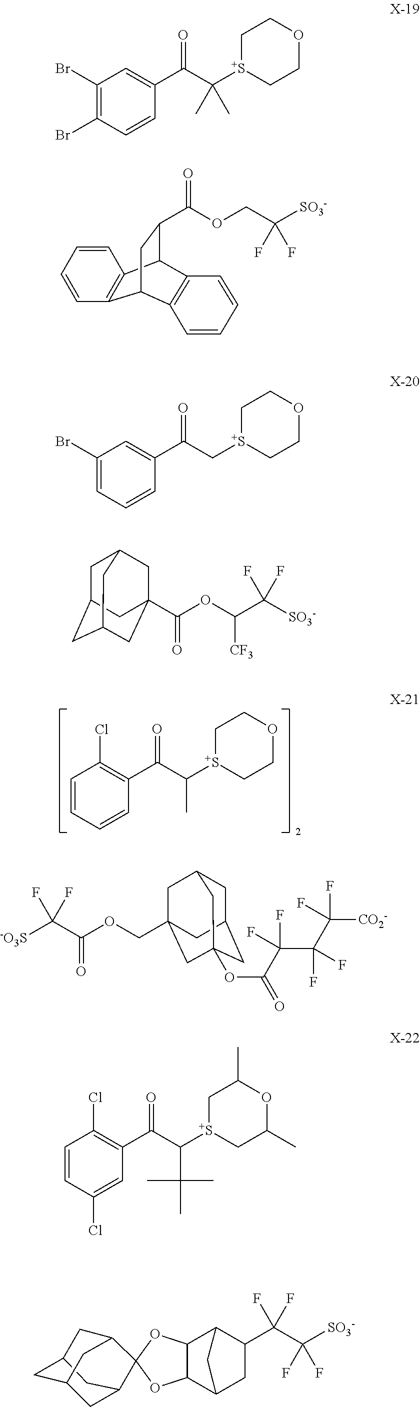

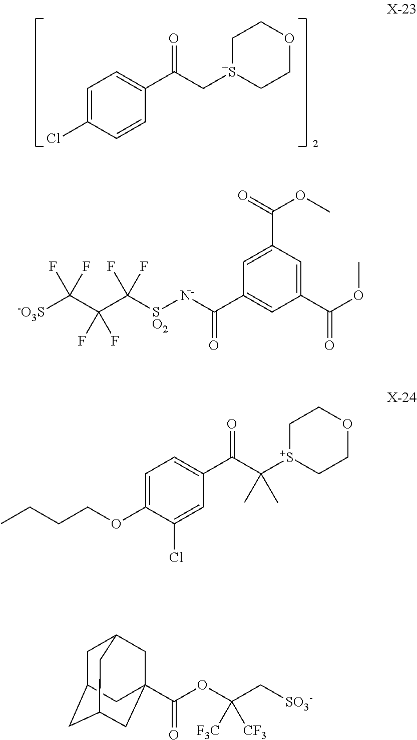

### Surfactant

The resist composition may include a surfactant. When a surfactant is included, it is possible to form a pattern having more excellent adhesiveness and less development defects.

The surfactant is preferably a fluorine-based and/or silicon-based surfactant.

Examples of the fluorine-based and/or silicon-based surfactant include surfactants disclosed in paragraphs [0218] and [0219] of WO 2018/193954A.

These surfactants may be used alone or two or more thereof.

When the resist composition includes a surfactant, the content of the surfactant is preferably 0.0001 to 2 mass % and more preferably 0.0005 to 1 mass % relative to the total solid content of the composition.

### Resist Film and Pattern-Forming Method

The procedure of a pattern-forming method using the resist composition is not particularly limited, but preferably has the following steps:
Step 1: a step of forming a resist film on a substrate using a resist composition;
Step 2: a step of exposing the resist film; and
Step 3: a step of developing the exposed resist film using a developer including an organic solvent.

Hereinafter, the procedure of each of the above steps will be described in detail.

### Step 1: Resist Film-Forming Step

Step 1 is a step of forming a resist film on a substrate using a resist composition.

The definition of the resist composition is as described above.

Examples of the method for forming a resist film on a substrate using a resist composition include a method of applying a resist composition onto a substrate.

The resist composition is preferably subjected to filter filtration as needed before the application. The pore size of the filter is preferably 0.1 m or less, more preferably 0.05 m or less, and further preferably 0.03 m or less. The filter is preferably a polytetrafluoroethylene, polyethylene, or nylon filter.

The resist composition can be applied on a substrate (example: silicon or silicon dioxide coating) that may be used for manufacturing an integrated circuit device by an appropriate coating method such as spinner or coater. The coating method is preferably spin coating using a spinner. The rotation speed when spin coating using a spinner is performed is preferably 1000 to 3000 rpm.

After coating of the resist composition, the substrate may be dried to form a resist film. As needed, various types of base films (an inorganic film, an organic film, or an antireflection film) may be formed on the under layer of the resist film.

Examples of the drying method include a method of drying by heating. The heating can be implemented by a method provided in a usual exposure machine and/or developing machine and may be implemented using a hot plate or the like. The heating temperature is preferably 80° C. to 150° C., more preferably 80° C. to 140° C., and further preferably 80° C. to 130° C. The heating time is preferably 30 to 1000 seconds, more preferably 60 to 800 seconds, and further preferably 60 to 600 seconds.

The film thickness of the resist film is not particularly limited, but is preferably 10 to 120 nm from the point that a fine pattern with higher precision can be formed. In particular, when EUV exposure is performed, the film thickness of the resist film is more preferably 10 to 65 nm and further preferably 15 to 50 nm. When ArF liquid immersion exposure is performed, the film thickness of the resist film is more preferably 10 to 120 nm and further preferably 15 to 90 nm.

A top coat may be formed on the upper layer of the resist film using a top coat composition.

The top coat composition is preferably one that is not mixed with the resist film and can be further homogeneously applied on the upper layer of the resist film. The top coat is not particularly limited, and a known top coat can be formed by a known method. For example, a top coat can be formed based on the description in paragraphs [0072] to [0082] of JP 2014-059543A.

For example, it is preferable to form a top coat including a basic compound as described in JP 2013-061648A on a resist film. Examples of the basic compound that can be included in the top coat include a basic compound that may be included in the resist composition.

The top coat preferably includes a compound that includes at least one group or bond selected from the group consisting of an ether bond, a thioether bond, a hydroxy group, a thiol group, a carbonyl bond, and an ester bond.

### Step 2: Exposure Step

Step 2 is a step of exposing the resist film.

Examples of the method for exposure include a method of irradiating the formed resist film with an active light ray or radioactive ray through a predetermined mask.

Examples of the active light ray and radioactive ray include infrared light, visible light, ultraviolet light, far ultraviolet light, extreme ultraviolet light, an X-ray, and an electron beam, and preferably far ultraviolet light having a wavelength of 250 nm or less, more preferably 220 nm or less, and particularly preferably 1 to 200 nm, specifically a KrF excimer laser (248 nm), an ArF excimer laser (193 nm), a F₂ excimer laser (157 nm), an EUV (13 nm), an X-ray, and an electron beam.

After the exposure, post-exposure heating treatment (also referred to as post-exposure bake) is preferably performed before performing development. The reaction of the exposed portion is accelerated by the post-exposure heating treatment, and the sensitivity and the pattern shape are more improved.

The heating temperature is preferably 80° C. to 150° C., more preferably 80° C. to 140° C., and further preferably 80° C. to 130° C.

The heating time is preferably 10 to 1000 seconds, more preferably 10 to 180 seconds, and further preferably 30 to 120 seconds.

The heating can be implemented by a method provided in a usual exposure machine and/or developing machine and may be performed using a hot plate or the like.

### Step 3: Developing Step

Step 3 is a step of developing the exposed resist film using a developer to from a pattern. The developer may be an alkali developer or a developer containing an organic solvent (hereinafter, also referred to as an organic-based developer).

Examples of the developing method include a method of dipping a substrate in a tank filled with a developer for a certain period of time (dip method), a method of developing by piling up and stationarily holding a developer on the surface of a substrate by surface tension (puddle method), a method by spraying a developer to the surface of a substrate (spray method), and a method of keeping ejecting a developer onto a substrate that is spinning at a certain speed while scanning a developer ejection nozzle at a certain speed (dynamic dispensing method).

In addition, after the step of performing development, a step of stopping the development may be implemented while replacing with another solvent.

The development time is not particularly limited as long as the resin at the unexposed portion is thoroughly dissolved, and is preferably 10 to 300 seconds and more preferably 20 to 120 seconds.

The temperature of the developer is preferably 0° C. to 50° C. and more preferably 15° C. to 35° C.

The organic-based developer is preferably a developer containing at least one organic solvent selected from the group consisting of a ketone-based solvent, an ester-based solvent, an alcohol-based solvent, an amide-based solvent, an ether-based solvent, and a hydrocarbon-based solvent.

The above-mentioned solvents may be used as a mixture of two or more thereof or may be used a mixture with a solvent other than the above or water. The moisture content in the whole developer is preferably less than 50 mass %, more preferably less than 20 mass %, and further preferably less than 10 mass %, and it is particularly preferred that moisture is not substantially contained.

The content of the organic solvent in the organic-based developer is preferably 50 mass % or more and 100 mass % or less, more preferably 80 mass % or more and 100 mass % or less, further preferably 90 mass % or more and 100 mass % or less, and particularly preferably 95 mass % or more and 100 mass % or less relative to the total amount of the developer.

### Other Step

The pattern-forming method preferably includes a step of washing with a rinse solution after Step 3.

The rinse solution that is used in the rinsing step after the developing step using an organic-based developer is not particularly limited as long as it does not dissolve a pattern, and a solution containing a common organic solvent can be used. As the rinse solution, it is preferable to use a rinse solution containing at least one organic solvent selected from the group consisting of a hydrocarbon-based solvent, a ketone-based solvent, an ester-based solvent, an alcohol-based solvent, an amide-based solvent, and an ether-based solvent.

The method of the rinsing step is not particularly limited, and examples thereof include a method keeping ejecting a rinse solution onto a substrate that is spinning at a certain speed (spin coating method), a method of immersing a substrate in a tank filled with a rinse solution for a certain period of time (dip method), and a method of spraying a rinse solution to the surface of a substrate (spray method).

The pattern-forming method of the present invention may include a heating step (post bake) after the rinsing step. In this step, the developer and rinse solution remaining between patterns and inside a pattern are removed by baking. In this step, the resist pattern is annealed, which also has an effect of reducing the surface roughness of the pattern. The heating step after the rinsing step is performed usually at 40° C. to 250° C. (preferably 90° C. to 200° C.) usually for 10 seconds to 3 minutes (preferably for 30 seconds to 120 seconds).

Etching treatment of the substrate using the formed pattern as a mask may be implemented. That is, using the pattern formed in Step 3 as a mask, a substrate (or a underlayer film and a substrate) may be processed to form a pattern on the substrate.

The method for processing a substrate (or an underlayer film and a substrate) is not particularly limited, but is preferably a method for forming a pattern on a substrate by using the pattern formed in Step 3 as a mask and performing dry etching of the substrate (or the underlayer film and the substrate). The dry etching is preferably oxygen plasma etching.

It is preferable that various materials used in the pattern-forming method of the present invention (e.g., a solvent, a developer, a rinse solution, a composition for forming an antireflection film, and a composition for forming a top coat) do not include impurities such as metals. The content of impurities included in these materials is preferably 1 mass ppm or less, more preferably 10 mass ppb or less, further preferably 100 mass ppt or less, particularly preferably 10 mass ppt or less, and most preferably 1 mass ppt or less. Here, examples of the metal impurities include Na, K, Ca, Fe, Cu, Mg, Al, Li, Cr, Ni, Sn, Ag, As, Au, Ba, Cd, Co, Pb, Ti, V, W, and Zn.

Examples of the method for removing impurities such as metals from various materials include filtration using a filter. The detail of filtration using a filter is described in paragraph [0321] of WO 2020/004306A.

In addition, examples of the method for decreasing impurities such as metals included in various materials include a method of selecting raw materials having low metal contents as the raw materials constituting the various materials, a method of filtering raw materials constituting various materials through a filter, and a method of performing distillation under conditions in which contamination is suppressed as much as possible by, for example, lining the inside of an apparatus with Teflon (registered trademark).

In addition to filter filtration, impurities may be removed with an adsorbent, or filter filtration and an adsorbent may be used in combination. As the adsorbent, a known adsorbent can be used, for example, an inorganic adsorbent, such as silica gel and zeolite, and an organic adsorbent, such as activated carbon, can be used. In order to decrease impurities such as metals included in various materials, it is necessary to prevent mixing of metal impurities during the manufacturing process. Whether metal impurities have been sufficiently removed from a manufacturing apparatus can be verified by measuring the content of metal components included in the washing liquid that has been used in the washing of the manufacturing apparatus. The content of metal components included in the used washing liquid is preferably 100 mass ppt (parts per trillion) or less, more preferably 10 mass ppt or less, and further preferably 1 mass ppt or less.

The organic process liquid such as the rinse solution may include an electroconductive compound for preventing breakdowns in chemical piping and various parts (such as filter, O-ring, and tube) caused by static electricity charge and subsequent static electricity discharge. The electroconductive compound is not particularly limited, but examples thereof include methanol. The amount of the compound is not particularly limited, but is preferably 10 mass % or less and more preferably 5 mass % or less in the point that preferable developing characteristics or rinsing characteristics are maintained.

As the chemical piping, for example, SUS (stainless steel), antistatic treated polyethylene or polypropylene, or piping coated with a fluorine resin (such as polytetrafluoroethylene or perfluoroalkoxy resin) can be used. As the filter and O-ring, similarly, antistatic treated polyethylene or polypropylene or a fluorine resin (such as polytetrafluoroethylene or perfluoroalkoxy resin) can be used.

### Method for Manufacturing Electronic Device

The present invention also relates to an electronic device-manufacturing method including the above-described pattern-forming method and an electronic device manufactured by this manufacturing method.

The electronic device of the present invention is suitably loaded on electric and electronic equipment (such as home electric appliances, OA (office automation), media-related equipment, optical equipment, and communication equipment).

### Examples

The present invention will now be described in further detail based on Examples. The materials, amounts to be used, ratios, processing contents, processing procedures, and so on shown in the following Examples can be changed as appropriate without departing from the gist of the present invention. Accordingly, the scope of the present invention should not be construed as being limited by the following Examples.

### Each Component of Active Light Ray Sensitive or Radioactive Ray Sensitive Resin Composition Resin

The resins (B-1 to B-16, RB-1, and RB-2) shown in Tables 1 and 2 were synthesized by a known method. The resins RB-1 and RB-2 correspond to resins for comparison.

The resins B-1 to B-16, RB-1, and RB-2 are shown below.

In the resins below, the compositional ratio of each repeating unit is on mol % basis.

The weight average molecular weight (Mw) and dispersity (Mw/Mn) of each of the resins B-1 to B-16, RB-1 to RB-2 were measured by GPC (carrier: tetrahydrofuran (THF)) (as polystyrene equivalent values). The compositional ratio (mol % ratio) of each resin was measured by ¹³C-NMR (nuclear magnetic resonance).

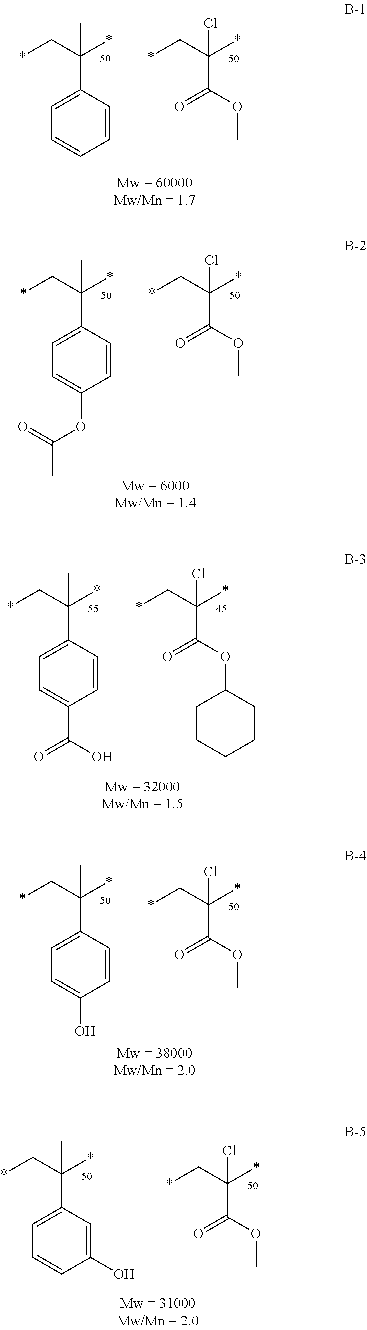

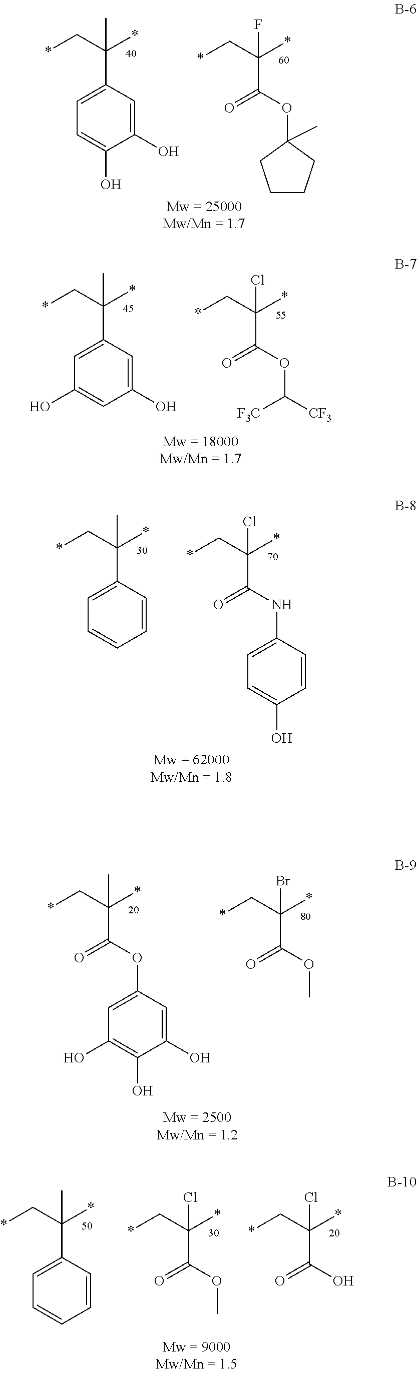

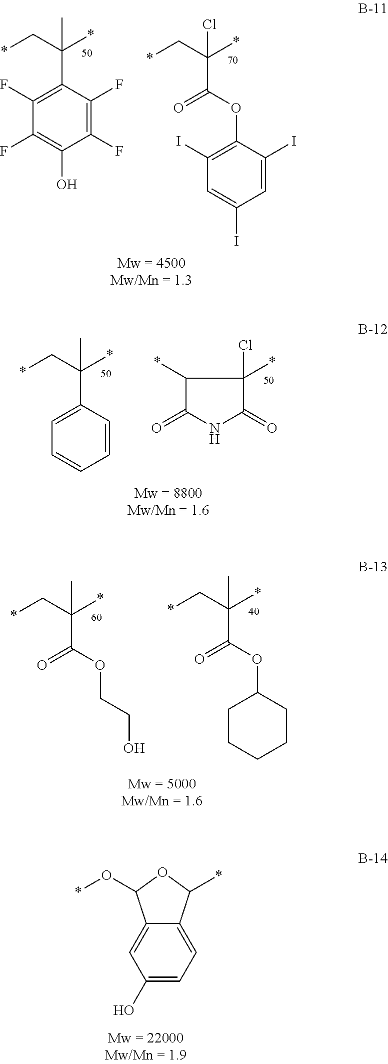

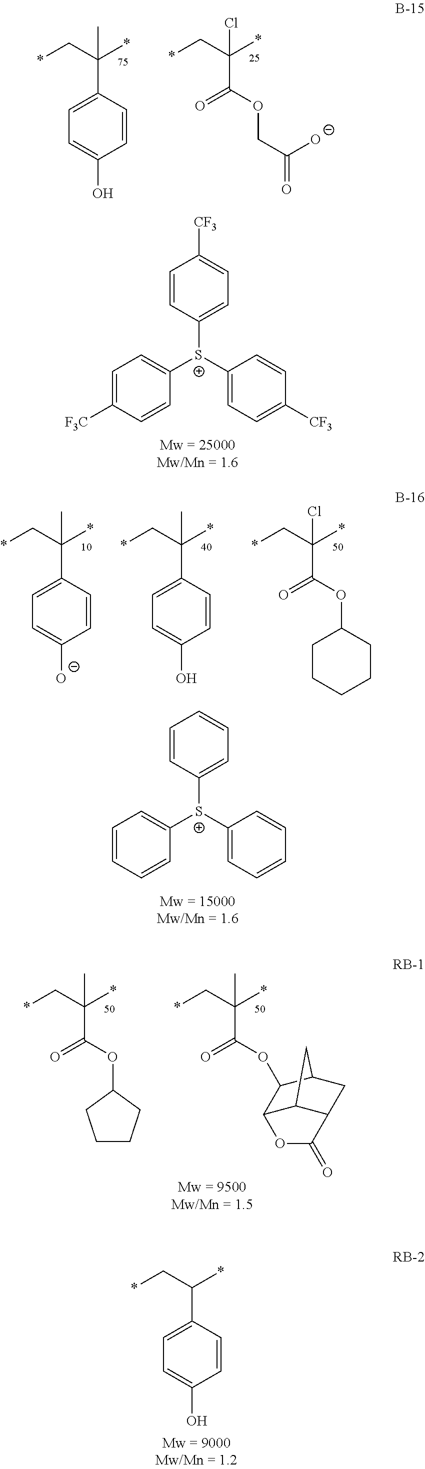

### Metal Compound

The metal compounds (A-1 to A-20) shown in Tables 1 and 2 are shown below.

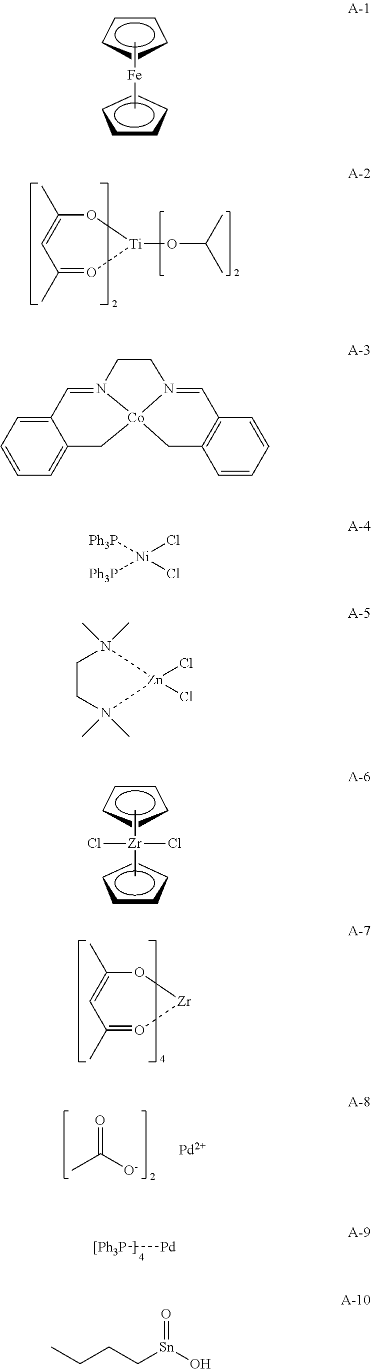

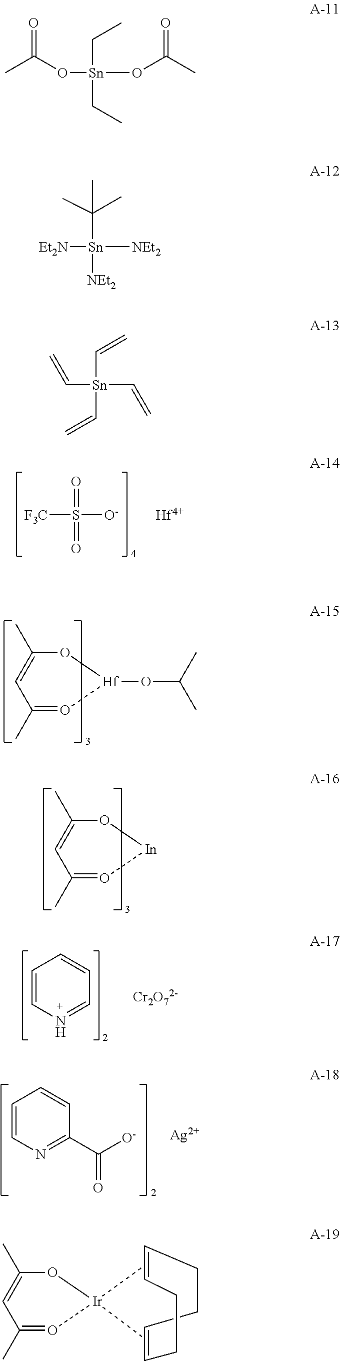

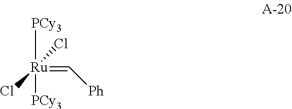

### Photodegradable Onium Salt

The photodegradable onium salts (C-1 to C-5) shown in Tables 1 and 2 are shown below.

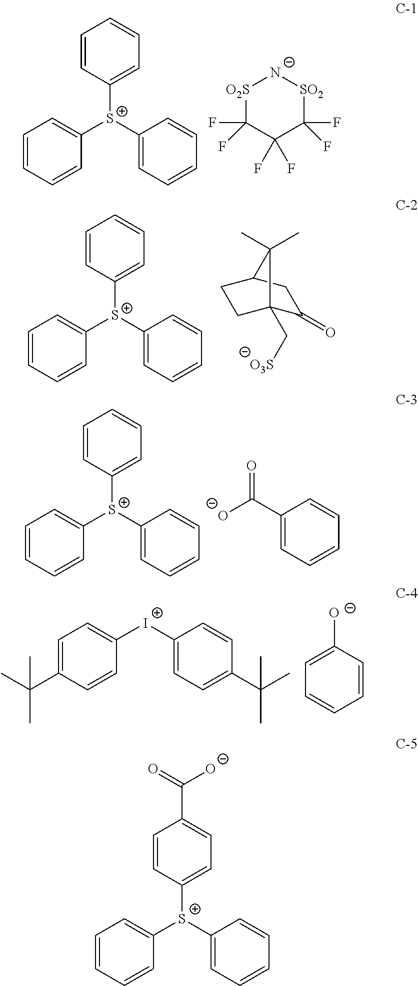

### Solvent

The solvents (D-1 to D-6) shown in Tables 1 and 2 are shown below.
D-1: propylene glycol monomethylether acetate (PGMEA)
D-2: propylene glycol monomethylether (PGME)
D-3: cyclohexanone
D-4: ethyl lactate
D-5: γ-butyrolactone
D-6: diacetone alcohol

### Developer and Rinse Solution

The developers and rinse solutions (E-1 to E-4) shown in Tables 1 and 2 are shown below.
E-1: butyl acetate
E-2: isopropyl acetate
E-3: butyl acetate:n-undecane=90:10 (mass ratio)
E-4: 4-methyl-2-pentanol

### Preparation of Active Light Ray Sensitive or Radioactive Ray Sensitive Resin Composition

The components shown in Table 1 were dissolved in the solvents shown in Table 1 to prepare solutions with a solid content concentration of 2.0 mass %. Each solution was filtered through a polyethylene filter having a pore size of 0.02 m to prepare each resist composition.

The solid content means all components other than the solvent. The resulting resist compositions were used in Examples and Comparative Examples.

In the tables, the column of “mass %” shows the content (mass %) of each component relative to the total solid content in the resist composition. The tables shows the used amount (part(s) by mass) of the solvent.

### Pattern Formation and Evaluation

### Pattern Formation by EUV Exposure and Evaluation: Examples 1-1 to 1-19 and Comparative Examples 1-1 to 1-3

### Pattern Formation

A composition AL412 (manufactured by Brewer Science, Inc.) for forming an underlayer film was applied onto a silicon wafer and was baked at 205° C. for 60 seconds to form a base film with a film thickness of 20 nm. The resist composition shown in Table 1 immediately after being manufactured was applied onto the base film and was baked at 100° C. for 60 seconds to form a resist film with a film thickness of 30 nm.

Pattern irradiation was performed to the silicon wafer having the obtained resist film using an EUV exposure apparatus (manufactured by Exitech Ltd., Micro Exposure Tool, NA0.3, Quadrupole, outer sigma: 0.68, inner sigma: 0.36). As the reticle, a mask having a line size of 20 nm was used at line:space=1:1.

The exposed resist film was baked at 100° C. for 60 seconds and was then developed by puddling with a developer shown in Table 1 for 30 seconds, only if stated, rinsing was performed by pouring a rinse solution shown in Table 1 for 10 seconds while rotating the wafer at a rotation speed of 1000 rpm, and then the wafer was rotated at a rotation speed of 4000 rpm for 30 seconds to obtain a line and space pattern with a pitch of 40 nm.

### Evaluation

### Optimum Exposure Amount (Sensitivity Evaluation)

The line width of the line and space pattern was measured using a length-measuring scanning electron microscope (SEM (manufactured by Hitachi High-Tech Corporation, CG-4100)) while changing the exposure amount, and the exposure amount when the line width was 20 nm was determined and was defined as the optimum exposure amount (mJ/cm²).

A smaller value indicating the optimum exposure amount indicates a higher sensitivity. More specifically, the optimum exposure amount is preferably 65 mJ/cm² or less and more preferably 50 mJ/cm² or less.

The results are shown in Table 1.

### Resolution

The exposure amount that reproduces a mask pattern with a line width of 20 nm under the exposing and developing conditions for formation of the above resist pattern was defined as the optimum exposure amount, and when the line width of a line and space pattern formed by further increasing the exposure amount beyond the optimum exposure amount is attenuated, the minimum critical line width resolved without any breaks in the pattern was defined as the value (nm) showing the resolution.

A smaller value indicating the resolution represents that a finer pattern can be resolved and shows a higher resolving power. More specifically, the resolution is preferably 18 nm or less, more preferably 16 nm or less, and further preferably 14 nm or less.

The results are shown in Table 1.

TABLE 1

| | Metal | | | | Photodegradable | | | | | | | |
|---|---|---|---|---|---|---|---|---|---|---|---|---|
| | compound | | | | onium salt | | | | | | Evaluation result | |
| Table 1 | (A) | | Resin (B) | | compound (C) | | Solvent (D) | | | | Optimum | |
| (EUV | | mass | | mass | | mass | | mass | | Rinse | exposure | |
| exposure) | Type | % | Type | % | Type | % | Type | ratio | Developer | solution | amount | Resolution |
| Example 1-1 | A-1 | 10 | B-2 | 80 | C-2 | 10 | D-1/D-2 | 80/20 | E-1 | — | 45 | 16 |
| Example 1-2 | A-2 | 16 | B-13 | 84 | — | — | D-1/D-2 | 70/30 | E-1 | — | 65 | 16 |
| Example 1-3 | A-3 | 15 | B-14 | 85 | — | — | D-1/D-2/D-5 | 70/25/5 | E-2 | — | 60 | 18 |
| Example 1-4 | A-4 | 10 | B-16 | 70 | C-1 | 20 | D-1/D-2 | 80/20 | E-1 | E-3 | 55 | 14 |
| Example 1-5 | A-5 | 22 | B-1 | 78 | — | — | D-1/D-2 | 40/60 | E-2 | — | 55 | 18 |
| Example 1-6 | A-6 | 16 | B-15 | 84 | — | — | D-1/D-2/D-5 | 80/10/10 | E-1 | — | 80 | 14 |
| Example 1-7 | A-7 | 5 | B-12 | 85 | C-1 | 10 | D-1/D-2 | 70/30 | E-1 | E-3 | 75 | 18 |
| Example 1-8 | A-8 | 15 | B-11 | 70 | C-1 | 15 | D-1/D-3 | 90/10 | E-2 | — | 85 | 14 |
| Example 1-9 | A-9 | 10 | B-1 | 90 | — | — | D-1/D-6 | 50/50 | E-1 | — | 85 | 18 |
| Example 1-10 | A-10 | 22 | B-2 | 78 | — | — | D-1/D-2 | 80/20 | E-1 | — | 50 | 16 |
| Example 1-11 | A-11 | 18 | B-3 | 77 | C-3 | 5 | D-1/D-2 | 70/30 | E-1 | E-3 | 45 | 14 |
| Example 1-12 | A-12 | 7 | B-4 | 83 | C-3 | 10 | D-1/D-2 | 70/30 | E-3 | — | 45 | 14 |
| Example 1-13 | A-13 | 15 | B-5 | 70 | C-4 | 15 | D-1/D-2 | 80/20 | E-1 | — | 50 | 14 |
| Example 1-14 | A-14 | 10 | B-6 | 90 | — | — | D-1/D-2 | 70/30 | E-3 | — | 45 | 16 |
| Example 1-15 | A-15 | 8 | B-7 | 92 | — | — | D-1/D-2 | 70/30 | E-1 | — | 45 | 14 |
| Example 1-16 | A-16 | 15 | B-8 | 85 | — | — | D-1/D-2 | 70/30 | E-3 | — | 60 | 16 |
| Example 1-17 | A-17 | 5 | B-9 | 85 | C-5 | 10 | D-1/D-4 | 80/20 | E-1 | — | 80 | 16 |
| Example 1-18 | A-18 | 3 | B-10 | 77 | C-3 | 20 | D-1/D-2 | 80/20 | E-3 | — | 55 | 16 |
| Example 1-19 | A-19 | 25 | B-15 | 75 | — | — | D-1/D-2/D-5 | 80/10/10 | E-1 | — | 75 | 14 |
| Comparative | — | — | B-1 | 80 | C-1 | 20 | D-1/D-2 | 80/20 | E-1 | — | Not | Not |
| Example 1-1 | | | | | | | | | | | resolved | resolved |
| Comparative | — | — | RB-1 | 85 | C-3 | 15 | D-1/D-2 | 70/30 | E-1 | — | Not | Not |
| Example 1-2 | | | | | | | | | | | resolved | resolved |
| Comparative | A-1 | 15 | RB-2 | 85 | — | — | D-1/D-2 | 80/20 | E-3 | — | 50 | 22 |
| Example 1-3 | | | | | | | | | | | | |

It was confirmed from the results of Table 1 that the resist compositions of Examples are excellent in sensitivity and can form patterns with excellent resolution.

It was also confirmed from comparison of Examples that when a resist composition includes one or more metal atoms selected from the group consisting of an iron atom, a titanium atom, a cobalt atom, a nickel atom, a zinc atom, a silver atom, an indium atom, a tin atom, and a hafnium atom (preferably one or more atoms selected from the group consisting of an iron atom, a tin atom, and a hafnium atom) as the specific metal compound, the sensitivity of the resist composition is more improved.

In addition, it was confirmed from comparison of Examples that when the specific resin in a resist composition includes a repeating unit represented by the above-described formula (1) (where, X represents a chlorine atom) and a repeating unit represented by the above-described formula (3) (where, C¹ represents a phenolic hydrogen atom or a carboxy group), a pattern with more improved resolution can be formed.

### Pattern Formation by EB Exposure and Evaluation: Examples 2-1 to 2-19 and Comparative Examples 2-1 to 2-3

### Pattern Formation

A composition DUV44 (manufactured by Brewer Science, Inc.) for forming an antireflection film was applied onto a 152-mm square mask blank with Cr as the outermost surface using ACTM (manufactured by Tokyo Electron Limited) and was baked at 205° C. for 60 seconds to form an underlayer film with a film thickness of 60 nm. The resist composition shown in Table 2 immediately after being manufactured was applied onto the underlayer film and was baked at 100° C. for 60 seconds to form a resist film with a film thickness of 30 nm. Consequently, a mask blank having a resist film was formed.

The mask blank having a resist film obtained by the above-described procedure was subjected to pattern irradiation using an electron beam exposure apparatus (manufactured by NuFlare Technology, Inc. EBM-9000, acceleration voltage: 50 kV). On this occasion, drawing was performed so as to form a line size of 22 nm and a line and space of 1:1.

The exposed resist film was baked at 100° C. for 60 seconds and was then developed by puddling with a developer shown in Table 2 for 30 seconds, only if stated, rinsing was performed by pouring a rinse solution shown in Table 2 for 10 seconds while rotating the wafer at a rotation speed of 1000 rpm, and then the wafer was rotated at a rotation speed of 4000 rpm for 30 seconds to obtain a line and space pattern with a pitch of 44 nm.

### Evaluation

Evaluation was implemented by the same procedures as that in “Pattern formation by EUV exposure and evaluation: Examples 1-1 to 1-19 and Comparative Examples 1-1 to 1-3” described above. The results are shown in Table 2.

In this evaluation, the optimum exposure amount is specifically preferably 250 mJ/cm² or less and more preferably 200 mJ/cm² or less. The resolution is specifically preferably 20 nm or less, more preferably 18 nm or less, and further preferably 16 nm or less.

TABLE 2

| | Metal | | | | Photodegradable | | | | | | | |
|---|---|---|---|---|---|---|---|---|---|---|---|---|
| | compound | | | | onium salt | | | | | | Evaluation result | |
| Table 2 | (A) | | Resin (B) | | compound (C) | | Solvent (D) | | | | Optimum | |
| (EB | | mass | | mass | | mass | | mass | | Rinse | exposure | |
| exposure) | Type | % | Type | % | Type | % | Type | ratio | Developer | solution | amount | Resolution |
| Example 2-1 | A-1 | 10 | B-2 | 80 | C-2 | 10 | D-1/D-2 | 80/20 | E-1 | — | 180 | 18 |
| Example 2-2 | A-2 | 16 | B-13 | 84 | — | — | D-1/D-2 | 70/30 | E-1 | — | 250 | 18 |
| Example 2-3 | A-3 | 15 | B-14 | 85 | — | — | D-1/D-2/D-5 | 70/25/5 | E-2 | — | 240 | 20 |
| Example 2-4 | A-4 | 10 | B-16 | 70 | C-1 | 20 | D-1/D-2 | 80/20 | E-1 | E-3 | 220 | 16 |
| Example 2-5 | A-5 | 22 | B-1 | 78 | — | — | D-1/D-2 | 40/60 | E-2 | — | 220 | 20 |
| Example 2-6 | A-6 | 16 | B-15 | 84 | — | — | D-1/D-2/D-5 | 80/10/10 | E-1 | — | 300 | 16 |
| Example 2-7 | A-7 | 5 | B-12 | 85 | C-1 | 10 | D-1/D-2 | 70/30 | E-1 | E-3 | 300 | 20 |
| Example 2-8 | A-8 | 15 | B-11 | 70 | C-1 | 15 | D-1/D-3 | 90/10 | E-2 | — | 290 | 16 |
| Example 2-9 | A-9 | 10 | B-1 | 90 | — | — | D-1/D-6 | 50/50 | E-1 | — | 280 | 20 |
| Example 2-10 | A-10 | 22 | B-2 | 78 | — | — | D-1/D-2 | 80/20 | E-1 | — | 200 | 18 |
| Example 2-11 | A-11 | 18 | B-3 | 77 | C-3 | 5 | D-1/D-2 | 70/30 | E-1 | E-3 | 180 | 16 |
| Example 2-12 | A-12 | 7 | B-4 | 83 | C-3 | 10 | D-1/D-2 | 70/30 | E-3 | — | 180 | 16 |
| Example 2-13 | A-13 | 15 | B-5 | 70 | C-4 | 15 | D-1/D-2 | 80/20 | E-1 | — | 190 | 16 |
| Example 2-14 | A-14 | 10 | B-6 | 90 | — | — | D-1/D-2 | 70/30 | E-3 | — | 180 | 18 |
| Example 2-15 | A-15 | 8 | B-7 | 92 | — | — | D-1/D-2 | 70/30 | E-1 | — | 180 | 16 |
| Example 2-16 | A-16 | 15 | B-8 | 85 | — | — | D-1/D-2 | 70/30 | E-3 | — | 230 | 18 |
| Example 2-17 | A-17 | 5 | B-9 | 85 | C-5 | 10 | D-1/D-4 | 80/20 | E-1 | — | 280 | 18 |
| Example 2-18 | A-18 | 3 | B-10 | 77 | C-3 | 20 | D-1/D-2 | 80/20 | E-3 | — | 220 | 18 |
| Example 2-19 | A-19 | 25 | B-15 | 75 | — | — | D-1/D-2/D-5 | 80/10/10 | E-1 | — | 280 | 16 |
| Comparative | — | — | B-1 | 80 | C-1 | 20 | D-1/D-2 | 80/20 | E-1 | — | Not | Not |
| Example 2-1 | | | | | | | | | | | resolved | resolved |
| Comparative | — | — | RB-1 | 85 | C-3 | 15 | D-1/D-2 | 70/30 | E-1 | — | Not | Not |
| Example 2-2 | | | | | | | | | | | resolved | resolved |
| Comparative | A-1 | 15 | RB-2 | 85 | — | — | D-1/D-2 | 80/20 | E-3 | — | 200 | 22 |
| Example 2-3 | | | | | | | | | | | | |

It was confirmed from the results of Table 2 that the resist compositions of Examples are excellent in sensitivity and can form patterns with excellent resolution.

It was also confirmed from comparison of Examples that when the specific metal compound in a resist composition includes one or more metal atoms selected from the group consisting of an iron atom, a titanium atom, a cobalt atom, a nickel atom, a zinc atom, a silver atom, an indium atom, a tin atom, and a hafnium atom (preferably one or more atoms selected from the group consisting of an iron atom, a tin atom, and a hafnium atom), the sensitivity of the resist composition is more improved.

In addition, it was confirmed from comparison of Examples that when the specific resin in a resist composition includes a repeating unit represented by the above-described formula (1) (where, X represents a chlorine atom) and a repeating unit represented by the above-described formula (3) (where, C¹ represents a phenolic hydrogen atom or a carboxy group), a pattern with more improved resolution can be formed.

What is claimed is:

1. An active light ray sensitive or radioactive ray sensitive resin composition comprising:
a metal compound;
a resin having a main chain that is decomposed by irradiation with an X-ray, an electron beam, or an extreme ultraviolet ray; and
a solvent, wherein
the metal compound includes one or more metal compounds selected from the group consisting of a metal complex, an organic metal salt, and an organic metal compound, and
the resin includes a repeating unit represented by a following formula (1) or a repeating unit represented by a following formula (XR): 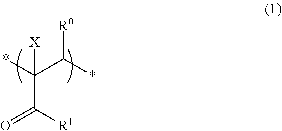
in the formula (1), X represents a halogen atom or a fluorinated alkyl group, R⁰ represents a hydrogen atom or an organic group, R¹ represents a substituent, and R⁰ and R¹ are optionally linked to each other to form a ring; 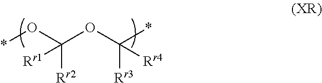
in the formula (XR), R^{r1} to R^{r4} each independently represent a hydrogen atom or a substituent, R^{r2} and R^{r3} are optionally bound to each other to form a ring, and * represents a binding site.

2. The active light ray sensitive or radioactive ray sensitive resin composition according to claim 1, wherein the resin includes one or more functional groups selected from the group consisting of a hydroxy group, a carboxyl group, an amino group, an amide group, a thiol group, and an acetoxy group.

3. The active light ray sensitive or radioactive ray sensitive resin composition according to claim 1, wherein the resin includes one or more functional groups selected from the group consisting of a phenolic hydroxy group and a carboxyl group.

4. The active light ray sensitive or radioactive ray sensitive resin composition according to claim 1, wherein the repeating unit represented by the formula (1) includes a repeating unit represented by a following formula (1A): 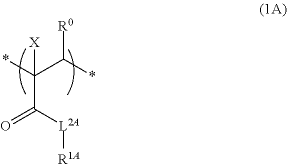
in the formula (1A), X represents a halogen atom or a fluorinated alkyl group, L^{2A} represents —O— or —N(R^{x})—, R^{x}, R⁰, and R^{1A} each independently represent a hydrogen atom or an organic group, and R⁰ and R^{1A} are optionally linked to each other to form a ring.

5. The active light ray sensitive or radioactive ray sensitive resin composition according to claim 1, wherein X represents a chlorine atom.

6. The active light ray sensitive or radioactive ray sensitive resin composition according to claim 1, wherein the resin includes a repeating unit represented by the formula (1) and a repeating unit represented by a following formula (3): 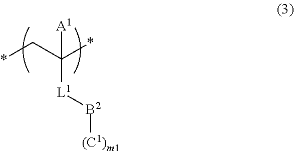
in the formula (3), A¹ represents a hydrogen atom or an alkyl group, L¹ represents a single bond or a divalent linker group, B² represents an (m1+1)-valent linker group, C¹ represents one or more specific functional groups selected from the group consisting of a hydroxy group, a carboxyl group, an amino group, an amide group, a thiol group, and an acetoxy group, m1 represents an integer of 1 or more, and when m1 represents an integer of 2 or more, a plurality of C¹'s are the same or different.

7. The active light ray sensitive or radioactive ray sensitive resin composition according to claim 6, wherein C¹ includes one or more functional groups selected from the group consisting of a phenolic hydroxy group and a carboxyl group.

8. The active light ray sensitive or radioactive ray sensitive resin composition according to claim 1, wherein the metal compound includes one or more metal atoms selected from the group consisting of an iron atom, a titanium atom, a cobalt atom, a nickel atom, a zinc atom, a silver atom, an indium atom, a tin atom, and a hafnium atom.

9. The active light ray sensitive or radioactive ray sensitive resin composition according to claim 1, wherein a content of the metal compound is 1 to 40 mass % relative to a content of the resin.

10. The active light ray sensitive or radioactive ray sensitive resin composition according to claim 1, further comprising a photodegradable onium salt compound.

11. A resist film formed using the active light ray sensitive or radioactive ray sensitive resin composition according to claim 1.

12. A pattern-forming method comprising:
a step of forming a resist film on a substrate using the active light ray sensitive or radioactive ray sensitive resin composition according to claim 1;
a step of exposing the resist film to an X-ray, an electron beam, or an extreme ultraviolet ray; and
a step of developing the exposed resist film using a developer.

13. A method for manufacturing an electronic device, the method comprising the pattern-forming method according to claim 12.

14. The active light ray sensitive or radioactive ray sensitive resin composition according to claim 2, wherein the resin includes one or more functional groups selected from the group consisting of a phenolic hydroxy group and a carboxyl group.

15. The active light ray sensitive or radioactive ray sensitive resin composition according to claim 2, wherein the repeating unit represented by the formula (1) includes a repeating unit represented by a following formula (1A): 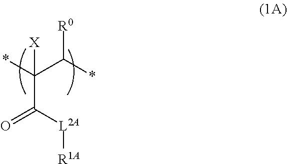
in the formula (1A), X represents a halogen atom or a fluorinated alkyl group, L^{2A} represents —O— or —N(R^{x})—, R^{x}, R⁰, and R^{1A} each independently represent a hydrogen atom or an organic group, and R⁰ and R^{1A} are optionally linked to each other to form a ring.

16. The active light ray sensitive or radioactive ray sensitive resin composition according to claim 2, wherein X represents a chlorine atom.

17. The active light ray sensitive or radioactive ray sensitive resin composition according to claim 2, wherein the resin includes a repeating unit represented by the formula (1) and a repeating unit represented by a following formula (3): 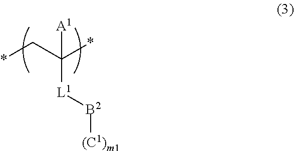
in the formula (3), A¹ represents a hydrogen atom or an alkyl group, L¹ represents a single bond or a divalent linker group, B² represents an (m1+1)-valent linker group, C¹ represents one or more specific functional groups selected from the group consisting of a hydroxy group, a carboxyl group, an amino group, an amide group, a thiol group, and an acetoxy group, m1 represents an integer of 1 or more, and when m1 represents an integer of 2 or more, a plurality of C¹'s are the same or different.

18. The active light ray sensitive or radioactive ray sensitive resin composition according to claim 17, wherein C¹ includes one or more functional groups selected from the group consisting of a phenolic hydroxy group and a carboxyl group.

19. The active light ray sensitive or radioactive ray sensitive resin composition according to claim 2, wherein the metal compound includes one or more metal atoms selected from the group consisting of an iron atom, a titanium atom, a cobalt atom, a nickel atom, a zinc atom, a silver atom, an indium atom, a tin atom, and a hafnium atom.

20. The active light ray sensitive or radioactive ray sensitive resin composition according to claim 2, wherein a content of the metal compound is 1 to 40 mass % relative to a content of the resin.
